(19) United States
(12) Patent Application Publication
(10) Pub. No.: US 2023/0197482 A1
(43) Pub. Date: Jun. 22, 2023

(54) POLISHING PAD AND METHOD FOR MANUFACTURING SEMICONDUCTOR DEVICE USING SAME

(71) Applicant: SKC solmics Co., Ltd., Gyeonggi-do (KR)

(72) Inventors: Chang Gyu IM, Seoul (KR); Jang Won SEO, Seoul (KR); Jong Wook YUN, Seoul (KR); Sung Hoon YUN, Seoul (KR)

(21) Appl. No.: 17/993,679

(22) Filed: Nov. 23, 2022

(30) Foreign Application Priority Data
Nov. 25, 2021 (KR) 10-2021-0164601

(51) Int. Cl. H01L 21/67

(52) U.S. Cl. CPC H01L 21/67219

(57) ABSTRACT

Through a combination of a multi-stage adhesive layer structure, a compressed region structure, and a barrier layer, the polishing pad according to the present disclosure can minimize the leakage of liquid components flowing through the interface between the window and the polishing pad and realize excellent long-term durability without leakage even when substantially applied to a polishing process for a long time. In the method for manufacturing a semiconductor device, the specific structure having the window of the polishing pad applied thereto as described above is combined with the optimal process conditions related to the polishing process so that the process efficiency can be further improved, and excellent quality can be secured in terms of polishing rate, polishing flatness, defect prevention, and the like.

### CROSS-REFERENCE TO RELATED APPLICATION(S)

This application claims priority to Korean Patent Application No. 10-2021-0164601, filed on Nov. 25, 2021, the disclosure of which is incorporated herein by reference in its entirety.

### TECHNICAL FIELD

The present disclosure relates to a polishing pad applied to a chemical mechanical planarization process of a semiconductor substrate as a part of a semiconductor device manufacturing process, and a method for manufacturing a semiconductor device having the same applied thereto.

### DESCRIPTION OF THE RELATED ART

A chemical mechanical planarization (CMP) or chemical mechanical polishing (CMP) process is used for various purposes in various fields. The CMP process is performed on a predetermined polishing surface of a polishing target, and may be performed for the purposes of planarization of the polishing surface, removal of aggregated materials, resolution of crystal lattice damage, removal of scratches and contaminants, etc.

The CMP process technology of the semiconductor process may be classified depending on a polishing target film or the surface shape after polishing. For example, it may be divided into single silicon or polysilicon depending on the polishing target film, and may be classified into a CMP process of various oxide films divided depending on the type of impurities, or a CMP process of metal films such as tungsten (W), copper (Cu), aluminum (Al), ruthenium (Ru), tantalum (Ta), etc. In addition, depending on the surface shape after polishing, it may be classified into a process of alleviating the roughness of the substrate surface, a process of flattening a step difference caused by multilayer circuit wiring, and an element isolation process for selectively forming circuit wiring after polishing.

The CMP process may be applied in plurality in the process of manufacturing a semiconductor device. The semiconductor device includes a plurality of layers, and each layer contains a complex and fine circuit pattern. Further, in recent semiconductor devices, individual chip sizes are reduced, and the pattern of each layer is evolving in a direction of becoming more complex and finer. Accordingly, in the process of manufacturing the semiconductor device, the purpose of the CMP process has been expanded to not only the purpose of planarizing circuit wiring, but also the purpose of applying separation of circuit wiring and improvement of a wiring surface, and as a result, more sophisticated and reliable CMP performance is required.

A polishing pad used in such a CMP process is a process component that processes a polishing surface to a required level through friction, and may be viewed as one of the most important factors in the thickness uniformity of the polishing target after polishing, flatness of the polishing surface, and polishing quality.

### SUMMARY

One embodiment is intended to provide, as a polishing pad to which a window for endpoint detection is applied, a polishing pad that minimizes a leak, which is a path of moisture permeation through the interface between the window and the polishing pad, and realizes excellent long-term durability without leakage even when substantially applied to a polishing process for a long time.

Another embodiment is intended to provide, as a method for manufacturing a semiconductor device having the polishing pad applied thereto, a method capable of manufacturing a semiconductor device in which a specific structure having the window of the polishing pad applied thereto is combined with optimal process conditions related to the polishing process to further improve the process efficiency and secure excellent quality in terms of polishing rate, polishing flatness, defect prevention, and the like.

In one embodiment, there is provided a polishing pad including: a polishing layer including a first surface that is a polishing surface and a second surface that is a rear surface thereof, and including a first through-hole penetrating from the first surface to the second surface, a window disposed in the first through-hole, and a support layer which is disposed on the second surface side of the polishing layer, includes a third surface of the polishing layer side and a fourth surface that is a rear surface thereof, and includes a second through-hole connected to the first through-hole while penetrating from the third surface to the fourth surface, wherein the second through-hole is smaller than the first through-hole, the lowermost end surface of the window is supported by the third surface, a first adhesive layer is included between the lowermost end surface of the window and the third surface, a second adhesive layer is included between the second surface and the third surface, and between the lowermost end surface of the window and the third surface, a barrier layer is included on one surface of the second adhesive layer, and the support layer includes a compressed region in a region corresponding to the lowermost end surface of the window.

The first adhesive layer may include a moisture-curable resin, and the second adhesive layer may include a thermoplastic resin.

The first adhesive layer may not be disposed between the side surface of the first through-hole and the side surface of the window.

The first adhesive layer may be disposed also between the side surface of the first through-hole and the side surface of the window.

The barrier layer may include one selected from the group consisting of a resin film, a metal-deposited resin film, an inorganic film-deposited resin film, a hydrophobic barrier coating resin film, a particle-dispersed resin film, an inorganic film, a metal film, and combinations thereof.

The support layer may include a non-compression region in a region except for the compressed region, and a percentage of the thickness of the compressed region compared to the thickness of the non-compression region may be 0.01% to 80%.

The first surface may include at least one groove, and the groove may have a depth of 100 µm to 1,500 µm and a width of 0.1 mm to 20 mm.

The first surface may include a plurality of grooves, the plurality of grooves may include concentric circular grooves, and the concentric circular grooves may have a distance between two adjacent grooves of 2 mm to 70 mm.

The lowermost end surface of the window may include a recess portion.

The recess portion may have a depth of 0.1 mm to 2.5 mm.

The window may include a non-foamed cured product of a window composition comprising a first urethane-based prepolymer, and the polishing layer may include a foamed cured product of a polishing layer composition comprising a second urethane-based prepolymer.

The Shore D hardness measured in a room temperature dry state with respect to the first surface may be smaller than the Shore D hardness measured in the room temperature dry state with respect to the uppermost end surface of the window.

In another embodiment, there is provided a method for manufacturing a semiconductor device, the method comprising steps of: providing a polishing pad provided with a polishing layer which includes a first surface that is a polishing surface and a second surface that is a rear surface thereof, includes a first through-hole penetrating from the first surface to the second surface, and includes a window disposed in the first through-hole; and polishing the polishing target while rotating the polishing pad and the polishing target relative to each other under pressurized conditions after disposing the polishing target on the first surface so that a surface to be polished of the polishing target and the first surface are in contact with each other, wherein the polishing target includes a semiconductor substrate, the polishing pad further includes a support layer disposed on the second surface side of the polishing layer, the support layer includes a third surface of the polishing layer side and a fourth surface that is a rear surface thereof, and includes a second through-hole connected to the first through-hole while penetrating from the third surface to the fourth surface, the second through-hole is smaller than the first through-hole, the lowermost end surface of the window is supported by the third surface, a first adhesive layer is included between the lowermost end surface of the window and the third surface, a second adhesive layer is included between the second surface and the third surface, and between the lowermost end surface of the window and the third surface, a barrier layer is included on one surface of the second adhesive layer, and the support layer includes a compressed region in a region corresponding to the lowermost end surface of the window.

The method for manufacturing a semiconductor device may further comprise a step of supplying a polishing slurry onto the first surface.

The polishing slurry may be sprayed onto the first surface through a supply nozzle, and the polishing slurry sprayed through the supply nozzle may have a flow rate of 10 ml/min to 1,000 ml/min.

The polishing target and the polishing pad may each have a rotation speed of 10 rpm to 500 rpm.

Through a combination of a multi-stage adhesive layer structure, a compressed region structure, and a barrier layer, the polishing pad can minimize the leakage of liquid components flowing through the interface between the window and the polishing pad and realize excellent long-term durability without leakage even when substantially applied to a polishing process for a long time.

In the method for manufacturing a semiconductor device, the specific structure having the window of the polishing pad applied thereto as described above is combined with the optimal process conditions related to the polishing process so that the process efficiency can be further improved, and excellent quality can be secured in terms of polishing rate, polishing flatness, defect prevention, and the like.

### BRIEF DESCRIPTION OF THE DRAWINGS

FIG. 1 is a plan view of a polishing pad according to one embodiment.

FIG. 2 schematically illustrates a cross-sectional view taken along line X-X′ of the polishing pad according to one embodiment of FIG. 1.

FIG. 3 schematically illustrates a cross-sectional view of a polishing pad according to another embodiment.

FIG. 4 is an enlarged schematic view of part B of FIG. 2.

FIG. 5 is an enlarged schematic view of part A of FIG. 2.

FIG. 6 schematically illustrates a cross section of a polishing pad according to another embodiment.

FIG. 7 schematically illustrates an air leak measurement process of the polishing pad

FIG. 8 is a schematic diagram schematically illustrating the method for manufacturing a semiconductor device according to one embodiment.

### DESCRIPTION OF SPECIFIC EMBODIMENTS

Advantages and features of the present disclosure, and methods for achieving them will become apparent with reference to embodiments to be described later. However, the present disclosure is not limited to the embodiments disclosed below, but will be embodied in various different forms, and these embodiments are only provided to allow the disclosure of the present disclosure to be complete, and fully inform those skilled in the art to which the present disclosure pertains of the scope of the invention, and the present disclosure is only defined by the scope of the claims.

The thicknesses of some components are enlarged in order to clearly express various layers or regions in the drawings. Further, in the drawings, the thickness of some layers and regions are exaggerated for convenience of description The same reference numerals refer to the same elements throughout the specification.

Further, in the present specification, when a part of a layer, film, region, plate, etc. is said to be “above” or “on” other part, this not only includes a case where the part is “directly above” the other part, but also includes a case where another part is interposed in the middle therebetween. On the contrary, when a part is said to be “directly above” other part, this means that another part is not interposed in the middle therebetween. Further, when a part of a layer, film, region, plate, etc. is said to be “under” or “below” other part, this not only includes a case where the part is “directly under” the other part, but also includes a case where another part is interposed therebetween. On the contrary, when a part is said to be “directly under” other part, this means that another part is not interposed therebetween.

In the present specification, modifiers such as “first” or “second” are used to distinguish cases where their higher-order components are different, and these modifiers alone do not mean that the mutual structures are specifically different types.

Hereinafter, embodiments according to the present disclosure will be described in detail.

In one embodiment of the present disclosure, there is provided a polishing pad including: a polishing layer including a first surface that is a polishing surface and a second surface that is a rear surface thereof, and including a first through-hole penetrating from the first surface to the second surface; a window disposed in the first through-hole; and a support layer which is disposed on the second surface side of the polishing layer, includes a third surface of the polishing layer side and a fourth surface that is a rear surface thereof, and includes a second through-hole connected to the first through-hole while penetrating from the third surface to the fourth surface, wherein the second through-hole is smaller than the first through-hole, the lowermost end surface of the window is supported by the third surface, a first adhesive layer is included between the lowermost end surface of the window and the third surface, a second adhesive layer is included between the second surface and the third surface, and between the lowermost end surface of the window and the third surface, a barrier layer is included on one surface of the second adhesive layer, and the support layer includes a compressed region in a region corresponding to the lowermost end surface of the window.

The polishing pad is one of raw and subsidiary materials essential for a polishing process requiring surface planarization and the like, and is one of important process components particularly in a semiconductor device manufacturing process. The purpose of the polishing pad is to planarize a non-flat structure and to promote subsequent processing convenience, such as removing surface defects and the like. Although the polishing process is a process applied to other technical fields other than the semiconductor technology field, it can be said that the precision of the polishing process required in the semiconductor manufacturing process is at the highest level when compared to other technical fields. Considering the recent tendency toward high integration and miniaturization of semiconductor devices, overall quality of the semiconductor devices may be greatly degraded even by very minute errors in a polishing process during a process of manufacturing the semiconductor devices. Therefore, for fine control of the polishing process, a polishing endpoint detection technique has been introduced so that polishing is stopped when the semiconductor substrate is precisely polished to a desired degree.

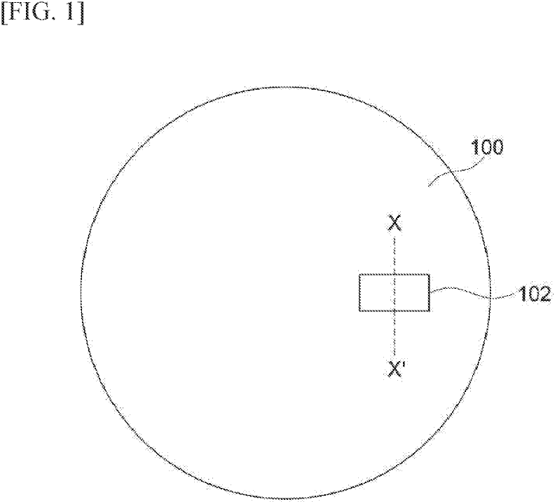

FIG. 1 schematically illustrates a plan view of a polishing pad 100 according to one embodiment. Referring to FIG. 1, the polishing pad 100 may include a window 102. Specifically, the polishing pad 100 overally has non-light transmitting properties, but a window 102 having locally light-transmitting properties is introduced, and thus the endpoint of polishing may be determined by sensing a change in the film quality by an optical signal such as a laser. Such a window 102 for endpoint detection is a component made of a material and physical properties that are different from a basic material and physical properties constituting the polishing layer of the polishing pad 100, and as the window 102 is introduced, a locally heterogeneous portion is created on the polishing surface of the polishing layer. Since the polishing of a semiconductor substrate utilizes the entire polishing surface of the polishing pad including the uppermost end surface of the window, minimizing the negative influence of the local heterogeneity of the portion where the window is introduced on the polishing of the semiconductor substrate may be considered as an important factor in determining the quality of the semiconductor device.

From this point of view, the polishing pad 100 according to one embodiment may secure a process advantage by the window 102 by applying a specific structural feature in introducing the window 102, and at the same time, function as a process component capable of manufacturing an excellent semiconductor device by minimizing negative factors due to the local heterogeneity of the portion where the window 102 is introduced.

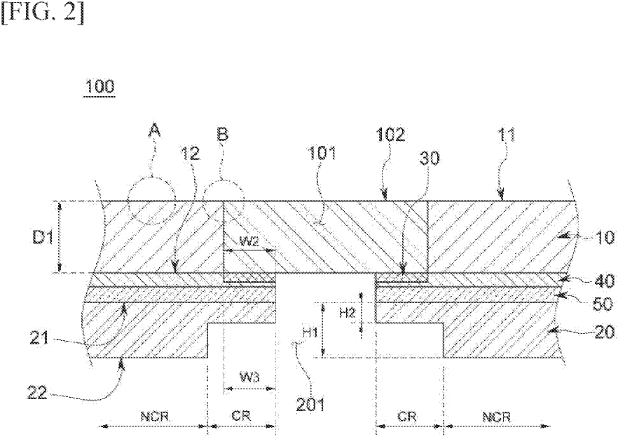

FIG. 2 schematically illustrates a cross-sectional view of the polishing pad 100 according to one embodiment, and specifically schematically illustrates a cross-sectional view taken along line X-X′ of FIG. 1. Referring to FIG. 2, the polishing pad 100 includes a polishing layer 10, and the polishing layer 10 includes a first surface 11 that is a polishing surface and a second surface 12 that is a rear surface thereof. In addition, the polishing layer 10 includes a first through-hole 101 penetrating from the first surface 11 to the second surface 12, and the window 102 is disposed in the first through-hole 101.

Further, the polishing pad 100 further includes a support layer 20 disposed on the second surface 12 side of the polishing layer 10. The support layer 20 includes a third surface 21 on the polishing layer 10 side and a fourth surface 22 that is a rear surface thereof, and includes a second through-hole 201 connected to the first through-hole 101 while penetrating from the third surface 21 to the fourth surface 22. The second through-hole 201 is formed to be connected to the first through-hole 101 so that the polishing pad 100 may include a light-pass penetrating the entire thickness from the uppermost end surface to the lowermost end surface, and the optical endpoint detection method through the window 102 may be efficiently applied.

In the polishing pad 100, the second through-hole 102 is smaller than the first through-hole 101, and the lowermost end surface of the window 101 may be supported by the third surface 21. Since the second through-hole 102 is formed to be smaller than the first through-hole 101, a support surface capable of supporting the window 101 is formed on the third surface 21. At this time, a first adhesive layer 30 is included between the lowermost end surface of the window and the third surface 21. In addition, a second adhesive layer 40 is included between the second surface 12 and the third surface 21, and between the lowermost end surface of the window and the third surface 21. In addition, a barrier layer 50 is included on one surface of the second adhesive layer 40. Accordingly, a multi-stage adhesive layer including the first adhesive layer 30 and the second adhesive layer 40 and a laminated structure of the barrier layer 50 are included between the lowermost end surface of the window and the third surface 21, and the leakage prevention effect may be greatly improved through the multi-stage adhesive structure and the laminated structure of the barrier layer. Specifically, the polishing process to which the polishing pad 100 is applied is performed while supplying a fluid such as a liquid slurry or the like on the polishing surface 11. At this time, components derived from such a fluid may flow into the interface between the side surface of the window 102 and the side surface of the first through-hole 101. When the fluid component permeated like this flows through the second through-hole 201 and into the polishing device at the lower end of the polishing pad 100, there is a risk of causing a failure of the polishing device or obstructing the accurate detection of the endpoint of the window 102. From this point of view, the polishing pad 100 may secure a support surface of the window 102 on the third surface 21 by forming the second through-hole 201 to be smaller than the first through-hole 101, and at the same time, may greatly improve the leakage prevention effect by forming the multi-stage adhesive layer including the first adhesive layer 30 and the second adhesive layer 40 and the laminated structure of the barrier layer on the support surface.

In one embodiment, the barrier layer 50 is a film-type layer with low moisture permeability, and is applied together with the multi-stage adhesive layer structure of the first adhesive layer 30 and the second adhesive layer 40 so that it may contribute to maximizing the leakage prevention effect of the polishing pad 100.

In one embodiment, the barrier layer 50 may include one selected from the group consisting of a resin film, a metal-deposited resin film, an inorganic film-deposited resin film, a hydrophobic barrier coating resin film, a particle-dispersed resin film, an inorganic film, a metal film, and combinations thereof.

In one embodiment, the barrier layer 50 may have a wet permeability of less than about 45 g/m²/day, for example, less than about 40 g/m²/day, for example, less than about 30 g/m²/day, for example, less than about 25 g/m²/day, for example, less than about 10 g/m²/day, for example, about 0 g/m²/day to about 40 g/m²/day, for example, about 0 g/m²/day to about 30 g/m²/day, for example, about 0 g/m²/day to about 25 g/m²/day, or for example, about 0 g/m²/day to about 10 g/m²/day. When the wet permeability of the barrier layer 50 satisfies such a range, the leakage prevention effect of the polishing pad 100 may be greatly improved.

In one embodiment, the barrier layer 50 may have a thickness of about 5 µm to about 50 µm, for example, about 5 µm to about 40 µm, for example, about 10 µm to about 30 µm, for example, about 10 µm to about 25 µm, or for example, about 10 µm to about 20 µm. Since the thickness of the barrier layer 50 satisfies such a range, a thickness effective in moisture prevention is ensured, and at the same time, the overall thickness of the polishing pad 100 of the barrier layer 50 is appropriately secured so that process efficiency may not be reduced. In addition, the barrier layer 50 may be advantageous to implement excellent durability based on firm adhesive power with the second adhesive layer 40 and the support layer 20 disposed on both surfaces thereof.

In one embodiment, the barrier layer 50 may have a density of about 0.8 g/cm³ to about 2.0 g/cm³, for example, about 0.8 g/cm³ to about 1.8 g/cm³, for example, about 1.0 g/cm³ to about 1.8 g/cm³, or for example, about 1.2 g/cm³ to about 1.6 g/cm³. The barrier layer 50 may be advantageous to contribute to the leakage prevention effect of the polishing pad 100 by corresponding to such a density range, and it may be more advantageous to secure mechanical durability between the second adhesive layer 40 and the support layer 20 which are disposed on both surfaces thereof.

In one embodiment, the barrier layer 50 may have a tensile strength of about 10 kgf/mm² to about 50 kgf/mm², for example, about 10 kgf/mm² to about 45 kgf/mm², for example, about 15 kgf/mm² to about 45 kgf/mm², or for example, about 20 kgf/mm² to about 40 kgf/mm². Since it has such a tensile strength, the barrier layer 50 may improve the leakage prevention effect, and at the same time, contribute to the improvement of the durability of the polishing pad 100, and the process efficiency of introducing the barrier layer 50 may be improved.

In one embodiment, the barrier layer 50 may have an elongation of about 100% to about 160%, for example, about 100% to about 150%, for example, about 105% to about 150%, or for example, about 110% to about 150%. Since it has such an elongation, the barrier layer 50 may improve the leakage prevention effect, and at the same time, contribute to the improvement of the durability of the polishing pad 100, and the process efficiency of introducing the barrier layer 50 may be improved.

The resin film may include, for example, one selected from the group consisting of polyester, polyamide (PA), polyketone, polysulfone, polycarbonate, fluoropolymer, polyacrylate, copolyetherester, copolyetheramide, polyurethane, polyvinylchloride, polytetrafluoroethylene, polyolefin, polyethylene terephthalate (PET), polypropylene (PP), nylon (PA), and combinations thereof.

The metal-deposited resin film may include, for example, a resin layer comprising one selected from the group consisting of polyester, polyamide (PA), polyketone, polysulfone, polycarbonate, fluoropolymer, polyacrylate, copolyetherester, copolyetheramide, polyurethane, polyvinylchloride, polytetrafluoroethylene, polyolefin, polyethylene terephthalate (PET), polypropylene (PP), nylon (PA), and combinations thereof; and a metal layer deposited on the resin layer. The metal layer may include, for example, one selected from the group consisting of aluminum (Al), zinc (Zn), tin (Sn), stainless steel, titanium (Ti), and combinations thereof.

The inorganic film-deposited resin film may include, for example, a resin layer comprising one selected from the group consisting of polyester, polyamide (PA), polyketone, polysulfone, polycarbonate, fluoropolymer, polyacrylate, copolyetherester, copolyetheramide, polyurethane, polyvinylchloride, polytetrafluoroethylene, polyolefin, polyethylene terephthalate (PET), polypropylene (PP), nylon (PA), and combinations thereof; and an inorganic film layer deposited on the resin layer. The inorganic film layer may include, for example, one selected from the group consisting of silicon oxide (SiOₓ), silicon nitride (SiNₓ), silicon oxynitride (SiOₓN_{y}), aluminum oxide (AlₓO_{y}), aluminum nitride (AlₓN_{y}), nickel oxide (NiOₓ), cobalt oxide (CoOₓ), magnesium oxide (MgO), titanium oxide (TiOₓ), and combinations thereof.

The hydrophobic barrier coating resin film may include, for example, a resin layer comprising one selected from the group consisting of polyester, polyamide (PA), polyketone, polysulfone, polycarbonate, fluoropolymer, polyacrylate, copolyetherester, copolyetheramide, polyurethane, polyvinylchloride, polytetrafluoroethylene, polyolefin, polyethylene terephthalate (PET), polypropylene (PP), nylon (PA), and combinations thereof; and a coating layer on the resin layer. The coating layer may include, for example, one selected from the group consisting of polyvinylidene chloride (PVDC), ethylene vinyl alcohol copolymer (EVOH), and a combination thereof.

In one embodiment, for each of the metal-deposited resin film, the inorganic film-deposited resin film, or the hydrophobic barrier coating resin film, the resin layer may have a thickness of, for example, about 4.5 µm to about 45 µm, for example, about 4.5 µm to about 30 µm, for example, about 4.5 µm to about 20 µm, for example, about 4.5 µm to about 15 µm, or for example, about 4.5 µm to about 12 µm.

In the hydrophobic barrier coating resin film, the coating layer may have a thickness of, for example, about 0.5 µm to about 5 µm, for example, about 0.5 µm to about 4.5 µm, or for example, about 0.5 µm to about 3 µm.

In the metal-deposited resin film, the metal layer may have a thickness of, for example, about 0.01 µm to about 0.5 µm, for example, about 0.01 µm to about 0.3 µm, or for example, about 0.01 µm to about 0.1 µm.

In the inorganic film-deposited resin film, the inorganic film may have a thickness of, for example, about 0.01 µm to about 0.5 µm, for example, about 0.01 µm to about 0.3 µm, or for example, about 0.01 µm to about 0.1 µm.

The particle-dispersed resin film may include, for example, a resin layer comprising one selected from the group consisting of polyester, polyamide (PA), polyketone, polysulfone, polycarbonate, fluoropolymer, polyacrylate, copolyetherester, copolyetheramide, polyurethane, polyvinylchloride, polytetrafluoroethylene, polyolefin, polyethylene terephthalate (PET), polypropylene (PP), nylon (PA), and combinations thereof; and particles dispersed in the resin layer. The particles may include, for example, one selected from the group consisting of titanium oxide (TiOₓ), polyurethane, calcium carbonate, graphene, fullerene, carbon nanotube, mica, montmorillonite, saponite, hectorite, vermiculite, and combinations thereof.

The inorganic film may include, for example, one selected from the group consisting of silicon oxide (SiOₓ), silicon nitride (SiNₓ), silicon oxynitride (SiOₓN_{y}), aluminum oxide (AlₓO_{y}), aluminum nitride (AlₓN_{y}), nickel oxide (NiOₓ), cobalt oxide (CoOₓ), magnesium oxide (MgO), titanium oxide (TiOₓ), and combinations thereof.

The metal layer may include, for example, one selected from the group consisting of aluminum (Al), zinc (Zn), tin (Sn), stainless steel, titanium (Ti), and combinations thereof.

In one embodiment, the barrier layer may include a hydrophobic barrier coating resin film or a metal-deposited resin film. The hydrophobic barrier coating resin film may include, for example, a polyethylene terephthalate (PET) resin layer; and a polyvinylidene chloride (PVDC) coating layer on the resin layer. The metal-deposited resin film may include, for example, a polyethylene terephthalate (PET) resin layer; and an aluminum (Al) deposition layer on the resin layer.

The polishing pad 100 partially includes a compressed region (CR) in the support layer 20 in order to maximize the leakage prevention effect. Specifically, referring to FIG. 2, the compressed region CR is formed in a region corresponding to the lowermost end surface of the window 102 of the support layer 20. At this time, the region corresponding to the lowermost end surface of the window 102 means a predetermined region including a portion corresponding to the lowermost end surface of the window 102 in the support layer 20, and the extension line of the side surface of the window 102 and the inner end of the compressed region CR do not necessarily coincide with each other. That is, it is sufficient that the compressed region CR is formed in a predetermined region to include all portions corresponding to the lowermost end surface of the window 102 from the side surface of the second through-hole 201 toward the inside of the support layer 20.

In one embodiment, the compressed region CR may have a continuous structure so as to include all portions corresponding to the lowermost end surface of the window 102 in a direction from the side surface of the second through-hole 201 toward the inside of the support layer. To describe it from other aspect, the compressed region CR is a continuous compression region including all portions corresponding to the lowermost end surface of the window 102, and may not include two or more compression regions divided by the non-compression region NCR. To describe it from another aspect, the compressed region CR may be a continuous compression region integrally formed to include all portions corresponding to the lowermost end surface of the window 102. That is, the compressed region CR is a continuous compression region integrally formed by being pressurized from the side of the fourth surface 22, which is the lower surface of the support layer 20, and does not include two or more compression regions having different pressurization directions during the formation process. Through this, not only may process efficiency be maximized, but also the high-density region formed by the pressurization process may be more advantageous in improving the leak prevention effect.

In this way, the compressed region CR is formed in the region corresponding to the lowermost end surface of the window 102 of the support layer 20 so that the compressed region CR may form a high density region compared to the non-compression region NCR, and through this, it may serve to effectively prevent a fluid component that can flow into the interface between the side surface of the window 102 and the side surface of the first through-hole 101 together with the multi-stage adhesive layer. As a result, the polishing pad 100 according to one embodiment has a multi-stage adhesive layer structure between the lowermost end surface of the window 102 and the third surface 21 and the compressed region CR structure of the support layer 20 organically combined therein so that it may implement a remarkably improved leakage prevention effect compared to the conventional art.

In one embodiment, the first adhesive layer 30 may include a moisture-curable resin, and the second adhesive layer 40 may include a thermoplastic resin. In one embodiment, the first adhesive layer 30 and the second adhesive layer 40 may be sequentially disposed in a direction from the lowermost end surface of the window 102 toward the third surface 21. The first adhesive layer 30 is an adhesive layer with which the fluid component leaked between the side surface of the window 102 and the side surface of the first through-hole 101 is in primary contact, and the first adhesive layer 30 may have a greatly improved leak prevention effect by including a moisture-curable resin. The second adhesive layer 40 not only is a configuration of a multi-stage adhesive layer between the lowermost end surface of the window 102 and the third surface 21, but also is a layer disposed between the second surface 12 and the third surface 21 in order to attach the polishing layer 10 and the barrier layer 50, and the second adhesive layer 40 is laminated with the first adhesive layer 30 by including a thermoplastic resin so that it may improve the leakage prevention effect and secure excellent interfacial durability between the polishing layer 10 and the barrier layer 50 at the same time.

The first adhesive layer 30 may include a moisture-curable product of a moisture-curable adhesive composition comprising: an aromatic diisocyanate; and a urethane-based prepolymer polymerized from a monomer component including a polyol. Here, ‘moisture-curable’ refers to properties in which moisture serves as a curing initiator, and the moisture-curable adhesive composition refers to an adhesive composition in which moisture in the air serves as a curing initiator. In the present specification, the term ‘prepolymer’ refers to a polymer having a relatively low molecular weight in which the polymerization degree is fixed at an intermediate stage to facilitate molding in the production of a cured product. The prepolymer itself may be subjected to an additional curing process such as heating and/or pressurization, or mixed and reacted with other polymerizable compound, for example, an additional compound such as a heterogeneous monomer or a heterogeneous prepolymer, and then molded into a final cured product.

Since the first adhesive layer 30 is derived from a moisture-curable adhesive composition comprising a urethane-based prepolymer polymerized from the monomer component, while greatly improving the interfacial adhesion between the window 102 and the first adhesive layer 30, it may be possible to greatly improve the leakage prevention effect based on excellent compatibility of the first adhesive layer 30 and the second adhesive layer 40.

More specifically, the first adhesive layer 30 may include a moisture-curable product of a moisture-curable adhesive composition comprising: an aromatic diisocyanate of Chemical Formula 1 below; a urethane-based prepolymer polymerized from a monomer component containing a diol having 2 to 10 carbon atoms; and an unreacted aromatic diisocyanate of Chemical Formula 1 below.

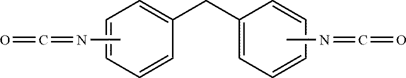

For example, the monomer component may contain a diol having 2 to 10 carbon atoms, for example, 3 to 10 carbon atoms, for example, 4 to 10 carbon atoms, or for example, 5 to 10 carbon atoms.

More specifically, the first adhesive layer 30 may include a moisture-curable product of a moisture-curable adhesive composition comprising: an aromatic diisocyanate of Chemical Formula 1 above; a urethane-based prepolymer polymerized from a monomer component containing a diol of Chemical Formula 2 below and a diol of Chemical Formula 3 below; and an unreacted aromatic diisocyanate of Chemical Formula 1 above.

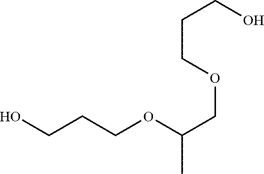

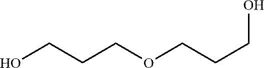

The adhesive composition may comprise about 90% by weight to about 99% by weight of the urethane-based prepolymer and about 1% by weight to about 10% by weight of the unreacted aromatic diisocyanate. For example, the urethane-based prepolymer may be contained in an amount of about 91% by weight to about 99% by weight, for example, about 93% by weight to about 99% by weight, or for example, about 95% by weight to about 99% by weight, and the unreacted aromatic diisocyanate may be contained in an amount of about 1% by weight to about 9% by weight, for example, about 1% by weight to about 7% by weight, or for example, about 1% by weight to about 5% by weight. The unreacted aromatic diisocyanate refers to a diisocyanate in which isocyanate groups (-NCO) at both terminals are present in a non-urethane-reacted state.

The adhesive composition for the first adhesive layer 30 may have a viscosity at room temperature of about 5,000 mPa.s to about 10,000 mPa.s, or for example, about 6,000 mPa.s to about 9,000 mPa.s. Here, the room temperature means a temperature within the range of about 20° C. to about 30° C. When the viscosity of the adhesive composition satisfies such a range, excellent process efficiency may be secured in the process of forming the first adhesive layer 30, and at the same time, the density of the first adhesive layer 30 formed by curing it may be more advantageous in the leak prevention effect.

Specifically, the second adhesive layer 40 may include one selected from the group consisting of a thermoplastic urethane-based adhesive, a thermoplastic acrylic adhesive, a thermoplastic silicone-based adhesive, and combinations thereof. The second adhesive layer 40 may obtain a technical advantage in terms of process efficiency improvement by including a thermoplastic resin compared to when the second adhesive layer 40 includes a thermosetting resin. Specifically, since it is difficult to apply a roll-to-roll process when a thermosetting adhesive is used as the second adhesive layer 40, the efficiency of mass production is lowered, and since a spray application method or the like should be applied instead of the roll-to-roll process, there is a risk of increasing the pad contamination degree due to scattering. That is, the second adhesive layer 40, as a layer formed in a large area between the second surface and the third surface, may increase process efficiency by applying a thermoplastic adhesive, may remarkably reduce the defective rate by preventing contamination of the polishing pad, and may be more advantageous in securing excellent compatibility with the first adhesive layer 40 derived from the moisture-curable adhesive in terms of securing the leakage prevention effect. In addition, since the second adhesive layer 40 includes a thermoplastic resin, excellent interfacial adhesion with the barrier layer 50 disposed on one surface thereof may be implemented.

In one embodiment, the second adhesive layer 40 may have a thickness of about 15 µm to about 40 µm, for example, about 15 µm to about 35 µm, for example, about 20 µm to about 35 µm, or for example, about 22 µm to about 32 µm. Since the thickness of the second adhesive layer 40 satisfies the above range, the second adhesive layer 40 may ensure sufficient adhesion between the second surface 12 and the third surface 21, and at the same time, it may be more advantageous in contributing to the leakage prevention effect as one configuration of the multi-stage adhesive layer on the lowermost end surface of the window 102. In addition, excellent interfacial adhesion with the barrier layer 50 disposed on one surface of the second adhesive layer 40 may be secured.

Referring to FIG. 2, in the polishing pad 100 according to one embodiment, the first adhesive layer 30 may not be disposed between the side surface of the window 102 and the side surface of the first through-hole 101. To describe it from other aspect, the first adhesive layer 30 may be in contact with the window 102 only through the lowermost end surface of the window 102 That is, the first adhesive layer 20 disposed between the side surface of the window 102 and the side surface of the first through-hole 101 may have a length of 0 µm. Through such a structure, a gap between the side surface of the window 102 and the side surface of the first through-hole 101 may be minimized, and as a result, a technical advantage may be obtained in terms of preventing the introduction itself of the liquid component or preventing process residues (debris) or the like from accumulating in the gap.

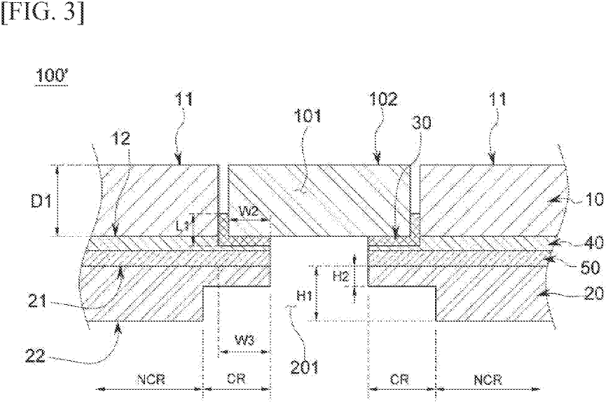

FIG. 3 schematically illustrates a cross-sectional view of the polishing pad 100′ according to other embodiment. Referring to FIG. 3, the first adhesive layer 30 may be also disposed between the side surface of the window 102 and the side surface of the first through-hole 101. To describe it from other aspect, the first adhesive layer 30 may be in contact with the window 102 through the lowermost end surface of the window 102 and the side surface of the window 102. The first adhesive layer 30 disposed between the side surface of the window 102 and the side surface of the first through-hole 101 may have a length L1 of, for example, about 0.1 µm to about 20 µm, for example, about 0.1 µm to about 10 µm, or for example, about 0.1 µm to about 5 µm. Through such a structure, it may be possible to obtain technical advantages in terms of minimizing the path through which the liquid component can move from the uppermost end surface of the window and the polishing surface and preventing the loading of debris.

Referring to FIGS. 2 or 3, the width W3 of the first adhesive layer 30 disposed on the lowermost end surface of the window 102 may be equal to or longer than the width W2 of the portion supported by the third surface 21 of the lowermost end surface of the window 102. Through such a structure, the distal end of the interface between the side surface of the window 102 and the side surface of the first through-hole 101 may be effectively sealed by the first adhesive layer 30, and the structure may be more advantageous in terms of improving the leakage prevention effect.

The first adhesive layer 30 disposed on the lowermost end surface of the window 102 may have a width W3 of about 2 mm to about 15 mm, for example, about 2 mm to about 12 mm, for example, about 2 mm to about 10 mm, for example, about 2.5 mm to about 9.5 mm, or for example, about 3.5 mm to about 9.5 mm. Since the width W3 of the first adhesive layer 30 satisfies the above range, and the correlation with the width W2 of the portion supported by the third surface 21 of the lowermost end surface of the window 102 satisfies that described above, it may be possible to increase the efficiency in terms of securing the structural durability supported by the support layer while securing the light transmission area of the window as wide as possible. In addition, it may be advantageous in terms of securing a path of sufficient length to block liquid components that may leak through the interface between the side surface of the window 102 and the side surface of the first through-hole 101.

Referring to FIG. 2, the support layer 20 may include a compressed region CR in a region corresponding to the lowermost end surface of the window 102 as described above, and at the same time, include a non-compression region NCR in a region except for the compressed region CR. The non-compression region NCR, as one having a predetermined porosity, may perform a buffering action so that an external force applied to the polishing pad 100 is not transmitted to the polishing target through the polishing surface 11, and may serve to support the polishing layer 10.

Referring to FIG. 2, the thickness H2 of the compressed region CR compared to the thickness H1 of the non-compression region NCR may have a percentage of about 0.01% to about 80%, for example, about 0.01% to about 60%, for example, about 0.01% to about 50%, for example, about 0.1% to about 50%, for example, about 1% to about 50%, for example, about 1% to about 45 %, for example, about 2% to about 45%, for example, about 5% to about 45%, for example, about 10% to about 45%, for example, about 15% to about 45%, or for example, about 20% to about 45%. That is, the value of H2/H1^{∗}100 may satisfy the above range. The compressed region CR is compressed to have a thickness that satisfies the above percentage range compared to the thickness of the non-compression region NCR so that it may be more advantageous in improving the leak prevention effect along with the multi-stage adhesive layer structure of the lowermost end surface of the window 102. In addition, the compressed region CR may configure a high-density region effective for preventing leakage without impairing the buffer function and support function of the non-compression region NCR.

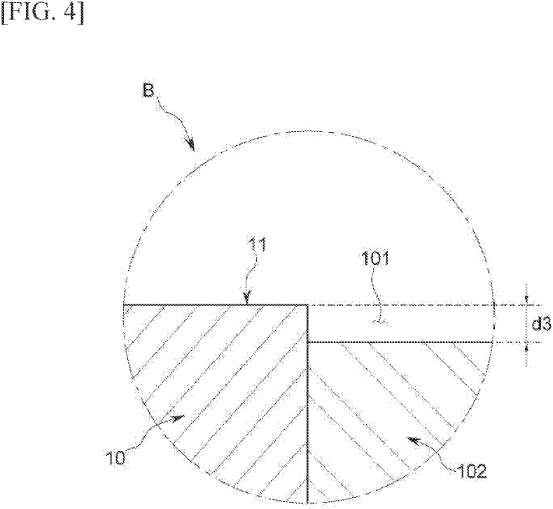

FIG. 4 is an enlarged schematic view of part B of FIG. 2. Referring to FIG. 4, the uppermost end surface of the window 102 may have a lower height than the first surface 11. Specifically, the uppermost end surface of the window 102 and the first surface 11 may have a height difference d3 of about 0 µm to about 300 µm, for example, about 0 µm to about 250 µm, for example, about 50 µm to about 250 µm, or for example, about 50 µm to about 150 µm. The height difference between the uppermost end surface of the window 102 and the first surface 11 has a correlation as described above so that it may be advantageous in terms of minimizing the possibility that the liquid component leaks through the interface between the side surface of the window 102 and the side surface of the first through-hole 101. More specifically, the surface hardness of the uppermost end surface of the window 102 and the first surface 11 reciprocally satisfies the relationship described later, and at the same time, the height difference between the uppermost end surface of the window 102 and the first surface 11 satisfies that described above so that the polishing interface may move smoothly in the process of performing polishing all over the uppermost end surface of the window 102 and the first surface 11, and it may be more advantageous in maximizing the leakage prevention effect through this.

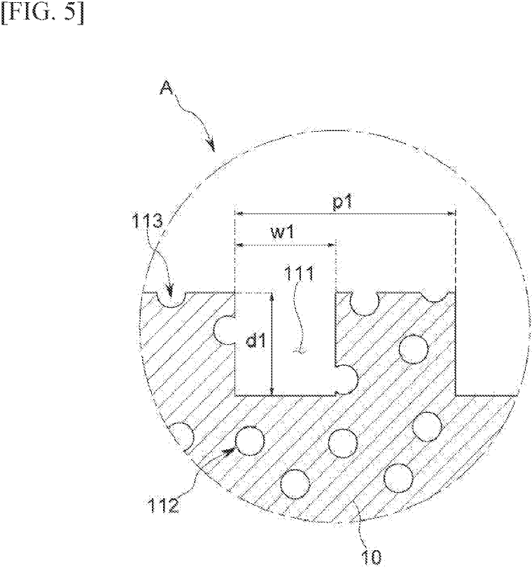

FIG. 5 is an enlarged schematic view of part A of FIG. 2. Referring to FIG. 5, the first surface 11 may include at least one groove 111. The groove 111 is a groove structure processed to a depth d1 smaller than the thickness D1 of the polishing layer 10, and may perform the function of securing the fluidity of the liquid component such as a polishing slurry, a cleaning solution, or the like applied onto the first surface 11 during the polishing process. The fluidity of the polishing slurry or the like applied to the first surface 11 is closely related to leakage through the interface between the side surface of the window 102 and the side surface of the first through-hole 101, and may contribute to maximizing the leakage prevention effect of the polishing pad 100 through an appropriate structural design of the groove 111.

In one embodiment, the planar structure of the polishing pad 100 may be substantially circular, and the at least one groove 111 may be a concentric circular structure disposed to be spaced apart from the center of the polishing layer 10 on the first surface 11 toward the end thereof at predetermined intervals. In another embodiment, the at least one groove 111 may be a radial structure continuously formed from the center of the polishing layer 10 on the first surface 11 toward the end thereof. In another embodiment, the at least one groove 111 may include a concentric circular structure and a radial structure at the same time.

In one embodiment, the polishing layer may have a thickness D1 of about 0.8 mm to about 5.0 mm, for example, about 1.0 mm to about 4.0 mm, for example, about 1.0 mm to 3.0 mm, for example, about 1.5 mm to about 3.0 mm, for example, about 1.7 mm to about 2.7 mm, or for example, about 2.0 mm to about 3.5 mm.

In one embodiment, the groove 111 may have a width w1 of about 0.1 mm to about 20 mm, for example, about 0.1 mm to about 15 mm, for example, about 0.1 mm to about 10 mm, for example, about 0.1 mm to about 5 mm, or for example, about 0.1 mm to about 15 mm

In one embodiment, the groove 111 may have a depth d1 of about 100 µm to about 1,500 µm, for example, about 200 µm to about 1,400 µm, for example, about 300 µm to about 1,300 µm, for example, about 400 µm to about 1,200 µm, for example, about 400 µm to about 1,000 µm, or for example, about 400 µm to about 800 µm.

In one embodiment, when the first surface 11 includes a plurality of grooves 111, and the plurality of grooves 111 include concentric circular grooves, the concentric circular grooves may have a pitch p1 defined as a distance between two adjacent grooves 111 of about 2 mm to about 70 mm, for example, about 2 mm to about 60 mm, for example, about 2 mm to about 50 mm, for example, about 2 mm to about 35 mm, for example, about 2 mm to about 10 mm, or for example, about 2 mm to about 8 mm.

The at least one groove 111 satisfies each or all of the depth d1, width w1, and pitch p1 of the aforementioned ranges so that the fluidity of the polishing slurry realized through this may be appropriately secured to maximize the effect of preventing leakage through the interface between the side surface of the window 102 and the side surface of the first through-hole 101. To describe it from other aspect, when the depth d1, width w1, and pitch p1 of the at least one groove 111 are out of the aforementioned ranges so that the fluidity of the polishing slurry implemented through this is excessively fast, or the flow rate per unit time is excessively high, there are concerns that the polishing slurry components may not perform their intended functions and may be discharged out of the first surface 11. On the contrary, when the fluidity of the polishing slurry is excessively slow or the flow rate per unit time is excessively low, there are concerns that the slurry components that have to perform physical and chemical polishing functions on the polishing surface may not perform their intended functions, and the amount of the slurry components escaping through the interface between the side surface of the window 102 and the side surface of the first through-hole 101 increases rapidly so that the long-term durability of the leakage prevention effect through the multi-stage adhesive structure of the first adhesive layer 30 and the second adhesive layer 40, the compressed region of the support layer, and the barrier layer may be lowered. That is, when the at least one groove 111 satisfies each or all of the depth d1, width w1, and pitch p1 of the aforementioned ranges, it may be advantageous in maximizing the leakage prevention effect through the multi-stage adhesive structure, the compressed region, and the barrier layer.

Referring to FIG. 5, the polishing layer 10 may be a porous structure including a plurality of pores 112. The plurality of pores 112 are dispersed throughout the polishing layer 10, and may serve to continuously create a predetermined roughness on the surface even in a process in which the polishing surface 11 is ground by a conditioner or the like during the polishing process. The plurality of pores 112 may be partially exposed to the outside on the first surface 11 of the polishing layer 10 to appear as fine concave portions 113 distinct from the grooves 111. The fine concave portions 113 may perform a function of determining the fluidity and mooring space of the polishing liquid or polishing slurry together with the grooves 112 during use of the polishing pad 100, and perform a function of physically providing frictional force to polishing of the surface to be polished.

The plurality of pores 112 may have an average pore size of about 10 µm to about 30 µm, for example, about 10 µm to about 25 µm, for example, about 15 µm to about 25 µm, or for example, about 18 µm to about 23 µm. In the average pore size, diameters of all pores were measured from the images obtained using image analysis software after observing the cross sections from images obtained by magnifying by 100 times a 1 mm² polishing surface obtained by cutting the polishing pad into a 1 mm x 1 mm square (thickness: 2 mm) using a scanning electron microscope (SEM), and the number of pores was obtained. The average pore size was derived as a number average value obtained by dividing the sum of diameters of a plurality of pores within 1 mm² of the polishing surface by the number of multiple pores. When the polishing layer 10 has a porous structure composed of a plurality of pores satisfying the average pore size, it may have appropriate mechanical properties, and such mechanical properties may exhibit excellent compatibility with the mechanical and physical properties of the window 102 so that it may be more advantageous in terms of leakage prevention by minimizing the occurrence of a leak in which the liquid component leaks between the polishing layer 10 and the window 102.

The first surface 11 may have a predetermined surface roughness due to the fine concave portions 113. In one embodiment, the first surface 11 may have a surface roughness Ra of about 1 µm to about 20 µm, for example, about 2 µm to about 18 µm, for example, about 3 µm to about 16 µm, for example, about 4 µm to about 14 µm, or for example, about 4 µm to about 10 µm. When the surface roughness Ra of the first surface 11 satisfies the above range, it may be advantageous in appropriately securing the fluidity of the polishing slurry due to the fine concave portions 113 in relation to the leakage prevention effect of the multi-stage adhesive structure, the compressed region, and the barrier layer.

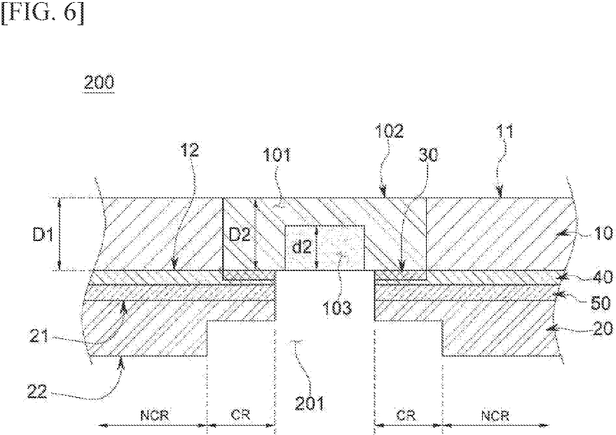

FIG. 6 schematically illustrates a cross section of the polishing pad 200 according to another embodiment. Referring to FIG. 6, the polishing pad 200 may further include a recess portion 103 in the lowermost end surface of the window 102. The recess portion 103 is a concave portion processed to have a predetermined depth d2 in a direction from the lowermost end surface of the window 102 toward the uppermost end surface, and it may enable more accurate endpoint detection by shortening the transmission path of light passing through the window 102 in order to detect the endpoint.

The recess portion 103 may have a depth d2 smaller than a thickness D2 of the window 102. The window 102 may have a thickness D2 of about 1.5 mm to about 3.0 mm, for example, about 1.5 mm to about 2.5 mm, or for example, about 2.0 mm to about 2.2 mm. The recess portion 103 may have a depth d2 of, for example, about 0.1 mm to about 2.5 mm, for example, about 0.1 mm to about 2.0 mm, for example, about 0.1 mm to about 1.5 mm, or for example, about 0.6 mm to about 1.0 mm. When the thickness D2 of the window 102 and the depth d2 of the recess portion 103 respectively or simultaneously satisfy the above ranges, the endpoint detection function may be excellently implemented. In addition, as the length of the path in which leakage may occur at the same time appears as a path having the same length as the depth of the window 102, an effective structure may be secured even in terms of preventing leakage.

In one embodiment, the Shore D hardness measured in a room temperature dry state with respect to the first surface 11 may be smaller than the Shore D hardness measured in the room temperature dry state with respect to the uppermost end surface of the window 102. Here, the room temperature dry state means a dry state in which a wet condition, which will be described later, is not treated at one temperature condition within the range of about 20°C to about 30°C. For example, the difference between the Shore D hardness measured in the room temperature dry state with respect to the first surface 11 and the Shore D hardness measured in the room temperature dry state with respect to the uppermost end surface of the window 102 may be about 1 to about 10, for example, about 1 to about 8, for example, about 2 to about 8, for example, about 2 to about 6, or for example, about 2 to about 5.

In one embodiment, the Shore D hardness measured in the room temperature dry state with respect to the uppermost end surface of the window 102 may be about 60 to about 70, for example, about 60 to about 68, or for example, about 60 to about 65. In one embodiment, the Shore D hardness measured in the room temperature dry state with respect to the first surface 11 may be about 50 to about 65, or for example, about 53 to about 65.

In one embodiment, the difference between the Shore D wet hardness measured at 30° C. with respect to the uppermost end surface of the window 102 and the Shore D wet hardness measured in the room temperature dry state with respect to the uppermost end surface of the window 102 may be about 0 to about 2.0, for example, about 0.5 to about 2.0, or for example, about 0.8 to about 2.0.

In one embodiment, the Shore D wet hardness measured at 50° C. with respect to the uppermost end surface of the window 102 may be smaller than the Shore D wet hardness measured in the room temperature dry state with respect to the uppermost end surface of the window 102. For example, the difference between the Shore D wet hardness measured at 50° C. with respect to the uppermost end surface of the window 102 and the Shore D wet hardness measured in the room temperature dry state with respect to the uppermost end surface of the window 102 may be about 1.0 to about 7.0, for example, about 1.0 to about 6.0, for example, about 2.0 to about 6.0, for example, about 3.5 to about 6.0, or for example, about 3.6 to about 6.0.

In one embodiment, the Shore D wet hardness measured at 70°C with respect to the uppermost end surface of the window 102 may be smaller than the Shore D wet hardness measured in the room temperature dry state with respect to the uppermost end surface of the window 102. For example, the difference between the Shore D wet hardness measured at 70° C. with respect to the uppermost end surface of the window 102 and the Shore D wet hardness measured in the room temperature dry state with respect to the uppermost end surface of the window 102 may be about 5 to about 10, for example, about 6 to about 10, for example, about 7 to about 10, or for example, about 7.5 to about 10.

In one embodiment, the Shore D wet hardness measured at 30° C. of the first surface 11 of the polishing layer 10 may be smaller than the Shore D wet hardness measured at 30° C. of the uppermost end surface of the window 102. For example, the difference between the Shore D wet hardness measured at 30° C. of the first surface 11 of the polishing layer and the Shore D wet hardness measured at 30° C. of the uppermost end surface of the window 102 may be about more than 0 and about 15 or less, for example, about 1 to about 15, or for example, about 2 to about 15.

In one embodiment, the Shore D wet hardness measured at 50°C of the first surface 11 of the polishing layer may be smaller than the Shore D wet hardness measured at 50° C. of the uppermost end surface of the window 102. For example, the difference between the Shore D wet hardness measured at 50° C. of the first surface 11 of the polishing layer and the Shore D wet hardness measured at 50° C. of the uppermost end surface of the window 102 may be about more than 0 and about 15 or less, for example, about 1 to about 25, for example, about 5 to about 25, or for example, about 5 to about 15.

In one embodiment, the Shore D wet hardness measured at 70° C. of the first surface 11 of the polishing layer may be smaller than the Shore D wet hardness measured at 70° C. of the uppermost end surface of the window 102. For example, the difference between the Shore D wet hardness measured at 70° C. of the first surface 11 of the polishing layer and the Shore D wet hardness measured at 70° C. of the uppermost end surface of the window 102 may be about more than 0 and about 15 or less, for example, about 1 to about 25, for example, about 5 to about 25, or for example, about 8 to about 16.

Here, the Shore D wet hardness is a surface hardness value measured after immersing the window 102 or the polishing layer 10 in water at the corresponding temperature for 30 minutes.

The polishing process to which the polishing pad 100 is applied is a process in which polishing is performed while mainly applying a liquid slurry onto the first surface 11. Further, the temperature of the polishing process may vary mainly in the range of about 30° C. to about 70° C. That is, the change in hardness of the uppermost end surface of the window 102 derived based on the Shore D hardness measured under temperature condition and wet environment similar to the actual process satisfies the aforementioned tendency, and at the same time, the hardness relationship between the first surface 11 and the uppermost end surface of the window 102 in the room temperature dry state satisfies the aforementioned range, and thus the polishing operation is smoothly performed while polishing is performed over the uppermost end surface of the window 102 and the entire first surface 11 so that it may be advantageous in minimizing the possibility of leakage through which the liquid component escapes to the interface between the side surface of the first through-hole 101 and the side surface of the window 102.

In one embodiment, the window 102 may include a non-foamed cured product of the window composition comprising the first urethane-based prepolymer. It may be more advantageous in securing light transmittance and appropriate surface hardness required for endpoint detection compared to when the window 102 includes a foamed cured product by including the non-foamed cured product. The ‘prepolymer’ refers to a polymer having a relatively low molecular weight in which the polymerization degree is fixed at an intermediate stage to facilitate molding in the production of a cured product. The prepolymer itself may be subjected to an additional curing process such as heating and/or pressurization, or mixed and reacted with other polymerizable compound, for example, an additional compound such as a heterogeneous monomer or a heterogeneous prepolymer, and then molded into a final cured product.

The first urethane-based prepolymer may be prepared by reacting a first isocyanate compound and a first polyol compound. The first isocyanate compound may include one selected from the group consisting of an aromatic diisocyanate, an aliphatic diisocyanate, an alicyclic diisocyanate, and combinations thereof. In one embodiment, the first isocyanate compound may include an aromatic diisocyanate and an alicyclic diisocyanate.

The first isocyanate compound may include, for example, one selected from the group consisting of 2,4-toluenediisocyanate (2,4-TDI), 2,6-toluenediisocyanate (2,6-TDI), naphthalene-1,5-diisocyanate, p-phenylenediisocyanate, tolidinediisocyanate, 4,4′-diphenylmethanediisocyanate, hexamethylenediisocyanate, dicyclohexylmethane diisocyanate, 4,4′-dicyclohexylmethane diisocyanate (H₁₂MDI), isophorone diisocyanate, and combinations thereof.

The first polyol compound may include, for example, one selected from the group consisting of a polyether polyol, a polyester polyol, a polycarbonate polyol, an acrylic polyol, and combinations thereof. The ‘polyol’ refers to a compound containing at least two hydroxyl groups (-OH) per molecule. In one embodiment, the first polyol compound may include a dihydric alcohol compound having two hydroxyl groups, that is, a diol or a glycol. In one embodiment, the first polyol compound may include a polyether polyol.

The first polyol compound may include, for example, one selected from the group consisting of polytetramethylene ether glycol (PTMG), polypropylene ether glycol, ethylene glycol, 1,2-propylene glycol, 1,3-propylene glycol, 1,2-butanediol, 1,3-butanediol, 2-methyl-1,3-propanediol, 1,4-butanediol, neopentyl glycol, 1,5-pentanediol, 3-methyl-1,5-pentanediol, 1,6-hexanediol, diethylene glycol (DEG), dipropylene glycol (DPG), tripropylene glycol, polypropylene glycol (PPG), and combinations thereof.

In one embodiment, the first polyol compound may have a weight average molecular weight (Mw) of about 100 g/mol to about 3,000 g/mol, for example, about 100 g/mol to about 2,000 g/mol, for example, about 100 g/mol to about 1,800 g/mol, for example, about 500 g/mol to about 1,500 g/mol, or for example, about 800 g/mol to about 1,200 g/mol.

In one embodiment, the first polyol compound may include a low molecular weight polyol having a weight average molecular weight (Mw) of about 100 g/mol or more and about less than 300 g/mol, and a high molecular weight polyol having a weight average molecular weight (Mw) of about 300 g/mol or more and about 1,800 g/mol or less. The low molecular weight polyol and the high molecular weight polyol that have the weight average molecular weights within the aforementioned ranges are appropriately mixed and used as the first polyol compound so that a non-foamed cured product having an appropriate crosslinking structure may be formed from the first urethane-based prepolymer, and the window 102 may be more advantageous in securing desired physical properties such as hardness and the like and desired optical properties such as light transmittance and the like.

The first urethane-based prepolymer may have a weight average molecular weight (Mw) of about 500 g/mol to about 2,000 g/mol, for example, about 800 g/mol to about 1,500 g/mol, for example, about 900 g/mol to about 1,200 g/mol, or for example, about 950 g/mol to about 1,100 g/mol. Since the first urethane-based prepolymer has a degree of polymerization corresponding to the weight average molecular weight (Mw) within the aforementioned range, the window composition is cured without foaming under predetermined process conditions, and thus it may be more advantageous in forming the window 102 having an appropriate surface hardness correlation with the polishing surface of the polishing layer 10, and the polishing proceeds smoothly over the polishing surface and the entire uppermost end surface of the window 102 through this so that it may be advantageous also in terms of preventing leakage.

In one embodiment, the first isocyanate compound may include an aromatic diisocyanate and an alicyclic diisocyanate. The aromatic diisocyanate may include, for example, 2,4-toluenediisocyanate (2,4-TDI) and 2,6-toluenediisocyanate (2,6-TDI), and the alicyclic diisocyanate may include dicyclohexylmethane diisocyanate (H₁₂MDI). Further, the first polyol compound may include, for example, polytetramethylene ether glycol (PTMG), diethylene glycol (DEG), and polypropylene glycol (PPG).

In the window composition, the total amount of the first polyol compound based on 100 parts by weight of the total amount of the first isocyanate compound in the total components for preparing the first urethane-based prepolymer may be about 100 parts by weight to about 250 parts by weight, for example, about 120 parts by weight to about 250 parts by weight, for example, about 120 parts by weight to about 240 parts by weight, for example, about 150 parts by weight to about 240 parts by weight, or for example, about 150 parts by weight to about 200 parts by weight.

In the window composition, the first isocyanate compound may include the aromatic diisocyanate, the aromatic diisocyanate may include 2,4-TDI and 2,6-TDI, and the content of 2,6-TDI may be about 1 part by weight to about 40 parts by weight, for example, about 1 part by weight to about 30 parts by weight, for example, about 10 parts by weight to about 30 parts by weight, or for example, about 15 parts by weight to about 30 parts by weight based on 100 parts by weight of 2,4-TDI.

In the window composition, the first isocyanate compound may include the aromatic diisocyanate and the alicyclic diisocyanate, and the total content of the alicyclic diisocyanate may be about 5 parts by weight to about 30 parts by weight, for example, about 10 parts by weight to about 30 parts by weight, or for example, about 15 parts by weight to about 30 parts by weight based on 100 parts by weight of the total content of the aromatic diisocyanate.

The relative content ratios of the respective components of the window composition satisfy the aforementioned ranges respectively or simultaneously so that the window 102 manufactured from the window composition may secure light transmittance required for the endpoint detection function, and the uppermost end surface of the window 102 may have an appropriate surface hardness at the same time. Accordingly, the uppermost end surface of the window 102 can form an appropriate surface hardness correlation with the polishing surface of the polishing layer 10 prepared from the polishing layer composition in which the relative content ratios of the respective components satisfy those to be described later respectively or simultaneously, and can smoothly perform polishing that proceeds while repeatedly passing through the polishing surface and the uppermost end surface of the window, so that the uppermost end surface of the window 102 may be more advantageous in effectively preventing a leakage phenomenon through between the side surface of the window 102 and the side surface of the first through-hole 101.

The window composition may have an isocyanate group content (NCO%) of about 6% by weight to about 10% by weight, for example, about 7% by weight to about 9% by weight, or for example, about 7.5% by weight to about 8.5% by weight. The isocyanate group content means a percentage by weight of an isocyanate group (-NCO) present as a free reactive group without being subjected to a urethane reaction in the total weight of the window composition. The isocyanate group content may be designed by comprehensively controlling the types and each content of the first isocyanate compound and the first polyol compound for preparing the first urethane-based prepolymer, the conditions of temperature, pressure, time, etc. of the process for preparing the first urethane-based prepolymer, and the type and content of an additive used in the preparation of the first urethane-based prepolymer. When the isocyanate group content of the window composition satisfies the above range, the window composition may be cured without foaming to secure an appropriate surface hardness, and it may be advantageous in securing an appropriate hardness correlation with the polishing layer in terms of being beneficial for maximizing the leakage prevention effect

The window composition may further comprise a curing agent. The curing agent is a compound for chemically reacting with the first urethane-based prepolymer to form a final cured structure in the window, and may include, for example, an amine compound or an alcohol compound. Specifically, the curing agent may include one selected from the group consisting of aromatic amines, aliphatic amines, aromatic alcohols, aliphatic alcohols, and combinations thereof.

The curing agent may include, for example, one selected from the group consisting of 4,4′-methylenebis(2-chloroaniline) (MOCA), diethyltoluenediamine (DETDA), diaminodiphenylmethane, dimethyl thio-toluene diamine (DMTDA), propanediol bis p-aminobenzoate, methylene bis-methylanthranilate, diaminodiphenylsulfone, m-xylylenediamine, isophorone diamine, ethylenediamine, diethylenetriamine, triethylenetetramine, polypropylenediamine, polypropylenetriamine, bis(4-amino-3-chlorophenyl)methane, and combinations thereof.

The curing agent may be contained in an amount of about 18 parts by weight to about 28 parts by weight, for example, about 19 parts by weight to about 27 parts by weight, or for example, about 20 parts by weight to about 26 parts by weight based on 100 parts by weight of the window composition.

In one embodiment, the curing agent may include an amine compound, and the molar ratio of the isocyanate group (-NCO) in the window composition to the amine group (-NH₂) in the curing agent may be about 1:0.60 to about 1:0.99, or for example, about 1:0.60 to about 1:0.95.

As described above, the window may include a non-foamed cured product of the window composition. Accordingly, the window composition may not comprise a foaming agent. Light transmittance required for endpoint detection may be secured by subjecting the window composition to the curing process without a foaming agent.

The window composition may further comprise an additive as needed. The type of the additive may include one selected from the group consisting of a surfactant, a pH adjuster, a binder, an antioxidant, a heat stabilizer, a dispersion stabilizer, and combinations thereof. The names such as ‘surfactant’ and ‘antioxidant’ are names arbitrarily designated based on the main roles of the corresponding materials, and each corresponding material does not necessarily perform only a function limited to the role by the corresponding name.

In one embodiment, the window 102 may have a light transmittance for light having one wavelength within a wavelength range of about 500 nm to about 700 nm with respect to a thickness of about 2 mm of about 1% to about 50%, for example, about 30% to about 85%, for example, about 30% to about 70%, for example, about 30% to about 60%, for example, about 1% to about 20%, for example, about 2% to about 20%, or for example, about 4% to about 15%. The light transmittance of the window may be controlled by whether the surface of the window is surface-treated or not, the composition of the window, and the like. The window 102 has such a light transmittance, and at the same time, the uppermost end surface of the window 102 and the polishing surface of the polishing layer 10 have the aforementioned hardness relationship so that the leakage prevention effect may be secured excellently.

In one embodiment, the polishing layer 10 may include a foamed cured product of the polishing layer composition comprising the second urethane-based prepolymer. The polishing layer 10 may have a pore structure by including a foamed cured product, and such a pore structure may perform the function of appropriately securing the fluidity of a polishing slurry applied to the polishing surface and the physical frictional force with the surface to be polished of the polishing target by forming a surface roughness on the polishing surface that cannot be formed with a non-foamed cured product. The ‘prepolymer’ refers to a polymer having a relatively low molecular weight in which the polymerization degree is fixed at an intermediate stage to facilitate molding in the cured product production. The prepolymer itself may be subjected to an additional curing process such as heating and/or pressurization, or mixed and reacted with other polymerizable compound, for example, an additional compound such as a heterogeneous monomer or a heterogeneous prepolymer, and then molded into a final cured product.

The second urethane-based prepolymer may be prepared by reacting a second isocyanate compound and a second polyol compound. The second isocyanate compound may include one selected from the group consisting of an aromatic diisocyanate, an aliphatic diisocyanate, an alicyclic diisocyanate, and combinations thereof. In one embodiment, the second isocyanate compound may include an aromatic diisocyanate. For example, the second isocyanate compound may include an aromatic diisocyanate and an alicyclic diisocyanate.

The second isocyanate compound may include, for example, one selected from the group consisting of 2,4-toluenediisocyanate (2,4-TDI), 2,6-toluenediisocyanate (2,6-TDI), naphthalene-1,5-diisocyanate, p-phenylenediisocyanate, tolidinediisocyanate, 4,4′-diphenylmethanediisocyanate, hexamethylenediisocyanate, dicyclohexylmethane diisocyanate, 4,4′-dicyclohexylmethane diisocyanate (H₁₂MDI), isophorone diisocyanate, and combinations thereof.

The second polyol compound may include, for example, one selected from the group consisting of a polyether polyol, a polyester polyol, a polycarbonate polyol, an acrylic polyol, and combinations thereof. The ‘polyol’ refers to a compound containing at least two hydroxyl groups (-OH) per molecule. In one embodiment, the second polyol compound may include a dihydric alcohol compound having two hydroxyl groups, that is, a diol or a glycol. In one embodiment, the second polyol compound may include a polyether polyol.

The second polyol compound may include, for example, one selected from the group consisting of polytetramethylene ether glycol (PTMG), polypropylene ether glycol, ethylene glycol, 1,2-propylene glycol, 1,3-propylene glycol, 1,2-butanediol, 1,3-butanediol, 2-methyl-1,3-propanediol, 1,4-butanediol, neopentyl glycol, 1,5-pentanediol, 3-methyl-1,5-pentanediol, 1,6-hexanediol, diethylene glycol (DEG), dipropylene glycol (DPG), tripropylene glycol, polypropylene glycol (PPG), and combinations thereof.

In one embodiment, the second polyol compound may include a low molecular weight polyol having a weight average molecular weight (Mw) of about 100 g/mol or more and about less than 300 g/mol, and a high molecular weight polyol having a weight average molecular weight (Mw) of about 300 g/mol or more and about 1,800 g/mol or less. The low molecular weight polyol and the high molecular weight polyol that have the weight average molecular weights within the aforementioned ranges are appropriately mixed and used as the second polyol compound so that a foamed cured product having an appropriate crosslinking structure may be formed from the second urethane-based prepolymer, and the polishing layer 10 may be more advantageous in forming a foamed structure having desired physical properties such as hardness and the like and pores of an appropriate size.

The second urethane-based prepolymer may have a weight average molecular weight (Mw) of about 500 g/mol to about 3,000 g/mol, for example, about 600 g/mol to about 2,000 g/mol, or for example, about 800 g/mol to about 1,000 g/mol. Since the second urethane-based prepolymer has a degree of polymerization corresponding to the weight average molecular weight (Mw) within the aforementioned range, the polishing layer composition is foamed and cured under predetermined process conditions so that it may be more advantageous in forming the polishing layer 10 with a polishing surface having an appropriate surface hardness correlation with the uppermost end surface of the window 102, and through this, the polishing proceeding over the polishing surface and the entire uppermost end surface of the window 102 is smooth so that it may be advantageous also in terms of preventing leakage through the interface between the window 102 and the polishing layer 10.

In one embodiment, the second isocyanate compound may include an aromatic diisocyanate and an alicyclic diisocyanate. The aromatic diisocyanate may include, for example, 2,4-toluenediisocyanate (2,4-TDI) and 2,6-toluenediisocyanate (2,6-TDI), and the alicyclic diisocyanate may include dicyclohexylmethane diisocyanate (H₁₂MDI). Further, the second polyol compound may include, for example, polytetramethylene ether glycol (PTMG) and diethylene glycol (DEG).

In the polishing layer composition, the total amount of the second polyol compound may be about 100 parts by weight to about 250 parts by weight, for example, about 110 parts by weight to about 250 parts by weight, for example, about 110 parts by weight to about 240 parts by weight, for example, about 110 parts by weight to about 200 parts by weight, for example, about 110 parts by weight to about 180 parts by weight, or for example, about 110 parts by weight or more and about less than 150 parts by weight based on 100 parts by weight of the total amount of the second isocyanate compound in the total components for preparing the second urethane-based prepolymer.

In the polishing layer composition, the second isocyanate compound may include the aromatic diisocyanate, the aromatic diisocyanate may include 2,4-TDI and 2,6-TDI, and the content of 2,6-TDI may be about 1 part by weight to about 40 parts by weight, for example, about 1 part by weight to about 30 parts by weight, for example, about 10 parts by weight to about 30 parts by weight, or for example, about 15 parts by weight to about 30 parts by weight based on 100 parts by weight of 2,4-TDI.

In the polishing layer composition, the second isocyanate compound may include the aromatic diisocyanate and the alicyclic diisocyanate, and the total content of the alicyclic diisocyanate may be about 5 parts by weight to about 30 parts by weight, for example, about 5 parts by weight to about 25 parts by weight, for example, about 5 parts by weight to about 20 parts by weight, or for example, about 5 parts by weight or more and about less than 15 parts by weight based on 100 parts by weight of the total content of the aromatic diisocyanate.

The relative content ratios of the respective components of the polishing layer composition satisfy the aforementioned ranges respectively or simultaneously so that the polishing surface of the polishing layer 10 prepared therefrom may have an appropriate pore structure and surface hardness. Accordingly, the polishing surface of the polishing layer 10 may form an appropriate surface hardness correlation with the uppermost end surface of the window 102 in which the relative content ratios of the respective components satisfy those described above respectively or simultaneously, and as a result, the polishing proceeding over the polishing surface and the entire uppermost end surface of the window 102 is smooth so that it may be advantageous also in terms of preventing leakage through the interface between the window 102 and the polishing layer 10.

The polishing layer composition may have an isocyanate group content (NCO%) of about 6% by weight to about 12% by weight, for example, about 6% by weight to about 10% by weight, or for example, about 6% by weight to about 9% by weight. The isocyanate group content means a percentage by weight of an isocyanate group (-NCO) present as a free reactive group without being subjected to a urethane reaction in the total weight of the preliminary composition. The isocyanate group content may be designed by comprehensively controlling the types and each content of the second isocyanate compound and the second polyol compound for preparing the second urethane-based prepolymer, the conditions such as temperature, pressure, time, etc. of the process for preparing the second urethane-based prepolymer, and the type and content of an additive used in the preparation of the second urethane-based prepolymer. When the isocyanate group content of the polishing layer composition satisfies the above range, the polishing layer composition is foamed and cured under predetermined process conditions so that it may be more advantageous in forming a polishing layer 10 with a polishing surface having an appropriate surface hardness correlation with the uppermost end surface of the window 102, and through this, polishing proceeding over the polishing surface and the entire uppermost end surface of the window 102 is smooth so that it may be advantageous also in terms of preventing leakage through the interface between the window 102 and the polishing layer 10.

The polishing layer composition may further comprise a curing agent. The curing agent is a compound for chemically reacting with the second urethane-based prepolymer to form a final cured structure in the polishing layer, and may include, for example, an amine compound or an alcohol compound. Specifically, the curing agent may include one selected from the group consisting of aromatic amines, aliphatic amines, aromatic alcohols, aliphatic alcohols, and combinations thereof.

The curing agent may include, for example, one selected from the group consisting of 4,4′-methylenebis(2-chloroaniline) (MOCA), diethyltoluenediamine (DETDA), diaminodiphenylmethane, dimethyl thio-toluene diamine (DMTDA), propanediol bis p-aminobenzoate, methylene bis-methylanthranilate, diaminodiphenylsulfone, m-xylylenediamine, isophorone diamine, ethylenediamine, diethylenetriamine, triethylenetetramine, polypropylenediamine, polypropylenetriamine, bis(4-amino-3-chlorophenyl)methane, and combinations thereof.

The curing agent may be contained in an amount of about 18 parts by weight to about 28 parts by weight, for example, about 19 parts by weight to about 27 parts by weight, or for example, about 20 parts by weight to about 26 parts by weight based on 100 parts by weight of the polishing layer composition.

In one embodiment, the curing agent may include an amine compound, and the molar ratio of the isocyanate group (-NCO) in the polishing layer composition to the amine group (-NH₂) in the curing agent may be about 1:0.60 to about 1:0.99, or for example, about 1 :0.60 to about 1 :0.95.

The polishing layer composition may further comprise a foaming agent. The foaming agent may include one selected from the group consisting of a solid-phase foaming agent, a gas-phase foaming agent, a liquid-phase foaming agent, and combinations thereof as a component for forming a pore structure in the polishing layer. In one embodiment, the foaming agent may include a solid-phase foaming agent, a gas-phase foaming agent, or a combination thereof.

The solid-phase foaming agent may have an average particle diameter of about 5 µm to about 200 µm, for example, about 20 µm to about 50 µm, for example, about 21 µm to about 50 µm, or for example, about 21 µm to about 40 µm. The average particle diameter of the solid-phase foaming agent may mean the average particle diameter of the thermally expanded particles themselves when the solid-phase foaming agent is thermally expanded particles as described below, and it may mean the average particle diameter of the particles after being expanded by heat or pressure when the solid-phase foaming agent is unexpanded particles as described below.

The solid-phase foaming agent may include expandable particles. The expandable particles are particles having properties of being expandable by heat or pressure, and the size thereof in the final polishing layer may be determined by heat or pressure applied in the process of preparing the polishing layer. The expandable particles may include thermally expanded particles, unexpanded particles, or a combination thereof. The thermally expanded particles are particles pre-expanded by heat, and refer to particles having a small or almost no size change due to heat or pressure applied in the process of preparing the polishing layer. The unexpanded particles are particles that have not been preliminarily expanded, and refer to particles which are expanded by heat or pressure applied in the process of preparing the polishing layer such that their final size is determined.

The expandable particles may include: a resin material shell; and an expansion-inducing component present in the inside encapsulated by the shell.

For example, the shell may include a thermoplastic resin, and the thermoplastic resin may be one or more selected from the group consisting of a vinylidene chloride-based copolymer, an acrylonitrile-based copolymer, a methacrylonitrile-based copolymer, and an acrylic copolymer.

The expansion-inducing component may include one selected from the group consisting of a hydrocarbon compound, a chlorofluoro compound, a tetraalkylsilane compound, and combinations thereof

Specifically, the hydrocarbon compound may include one selected from the group consisting of ethane, ethylene, propane, propene, n-butane, isobutane, n-butene, isobutene, n-pentane, isopentane, neopentane, n-hexane, heptane, petroleum ether, and combinations thereof.

The chlorofluoro compound may include one selected from the group consisting of trichlorofluoromethane (CCl₃F), dichlorodifluoromethane (CCl₂F₂), chlorotrifluoromethane (CClF₃), tetrafluoroethylene (CClF₂-CClF₂), and combinations thereof.

The tetraalkylsilane compound may include one selected from the group consisting of tetramethylsilane, trimethylethylsilane, trimethylisopropylsilane, trimethyl-n-propylsilane, and combinations thereof.

The solid-phase foaming agent may optionally include inorganic component-treated particles. For example, the solid-phase foaming agent may include inorganic component-treated expandable particles. In one embodiment, the solid-phase foaming agent may include silica (SiO2) particle-treated expandable particles. The inorganic component treatment of the solid-phase foaming agent may prevent aggregation between a plurality of particles. The inorganic component-treated solid-phase foaming agent may have different chemical, electrical, and/or physical properties of the foaming agent surface from the inorganic component-untreated solid-phase foaming agent.

The solid-phase foaming agent may be contained in an amount of about 0.5 parts by weight to about 10 parts by weight, for example, about 1 part by weight to about 3 parts by weight, for example, about 1.3 parts by weight to about 2.7 parts by weight, or for example, about 1.3 parts by weight to about 2.6 parts by weight based on 100 parts by weight of the urethane-based prepolymer.

The type and content of the solid-phase foaming agent may be designed depending on the desired pore structure and physical properties of the polishing layer.

The gas-phase foaming agent may include an inert gas. The gas-phase foaming agent may be used as a pore-forming element by being inputted in a process in which the second urethane-based prepolymer and the curing agent are reacted.

The type of inert gas is not particularly limited as long as it is a gas that does not participate in the reaction between the second urethane-based prepolymer and the curing agent. For example, the inert gas may include one selected from the group consisting of nitrogen gas (N₂), argon gas (Ar), helium gas (He), and combinations thereof. Specifically, the inert gas may include nitrogen gas (N₂) or argon gas (Ar).

The type and content of the gas-phase foaming agent may be designed depending on the desired pore structure and physical properties of the polishing layer.

In one embodiment, the foaming agent may include a solid-phase foaming agent. For example, the foaming agent may consist only of a solid-phase foaming agent.

The solid-phase foaming agent may include expandable particles, and the expandable particles may include thermally expanded particles. For example, the solid-phase foaming agent may consist only of thermally expanded particles. When the solid-phase foaming agent consists only of the thermally expanded particles without including the unexpanded particles, the variability of the pore structure is lowered, but the preliminary predictability is increased so that it may be advantageous in implementing homogeneous pore properties over the entire region of the polishing layer.

In one embodiment, the thermally expanded particles may be particles having an average particle diameter of about 5 µm to about 200 µm. The thermally expanded particles may have an average particle diameter of about 5 µm to about 100 µm, for example, about 10 µm to about 80 µm, for example, about 20 µm to about 70 µm, for example, about 20 µm to about 50 µm, for example, about 30 µm to about 70 µm, for example, about 25 µm to about 45 µm, for example, about 40 µm to about 70 µm, or for example, about 40 µm to about 60 µm. The average particle diameter is defined as D50 of the thermally expanded particles.

In one embodiment, the thermally expanded particles may have a density of about 30 kg/m³ to about 80 kg/m³, for example, about 35 kg/m³ to about 80 kg/m³, for example, about 35 kg/m³ to about 75 kg/m³, for example, about 38 kg/m³ to about 72 kg/m³, for example, about 40 kg/m³ to about 75 kg/m³, or for example, about 40 kg/m³ to about 72 kg/m³.

In one embodiment, the foaming agent may include a gas-phase foaming agent. For example, the foaming agent may include a solid-phase foaming agent and a gas-phase foaming agent. Matters regarding the solid-phase foaming agent are the same as described above.

The gas-phase foaming agent may be injected through a predetermined injection line during a process in which the second urethane-based prepolymer, the solid-phase foaming agent, and the curing agent are mixed. The gas-phase foaming agent may have an injection rate of about 0.8 L/min to about 2.0 L/min, for example, about 0.8 L/min to about 1.8 L/min, for example, about 0.8 L/min to about 1.7 L/min, for example, about 1.0 L/min to about 2.0 L/min, for example, about 1.0 L/min to about 1.8 L/min, or for example, about 1.0 L/min to about 1.7 L/min.

The polishing layer composition may further comprise an additive as needed. The type of the additive may include one selected from the group consisting of a surfactant, a pH adjuster, a binder, an antioxidant, a heat stabilizer, a dispersion stabilizer, and combinations thereof. The names such as ‘surfactant’ and ‘antioxidant’ are names arbitrarily designated based on the main roles of the corresponding materials, and each corresponding material does not necessarily perform only a function limited to the role by the corresponding name.

The surfactant is not particularly limited as long as it is a material that serves to prevent a phenomenon such as aggregation or overlapping of pores. For example, the surfactant may include a silicone-based surfactant.

The surfactant may be used in an amount of about 0.2 parts by weight to about 2 parts by weight based on 100 parts by weight of the second urethane-based prepolymer. Specifically, the surfactant may be contained in an amount of about 0.2 parts by weight to about 1.9 parts by weight, for example, about 0.2 parts by weight to about 1.8 parts by weight, for example, about 0.2 parts by weight to about 1.7 parts by weight, for example, about 0.2 parts by weight to about 1.6 parts by weight, for example, about 0.2 parts by weight to about 1.5 parts by weight, or for example, about 0.5 parts by weight to about 1.5 parts by weight based on 100 parts by weight of the second urethane-based prepolymer. When the surfactant is contained in an amount within the above range, pores derived from the gas-phase foaming agent may be stably formed and maintained in the mold.

The reaction rate controlling agent serves to promote or delay the reaction, and a reaction accelerator, a reaction retarder, or both thereof may be used depending on the purpose. The reaction rate controlling agent may include a reaction accelerator. For example, the reaction accelerator may be one or more reaction accelerators selected from the group consisting of a tertiary amine-based compound and an organometallic compound.

Specifically, the reaction rate controlling agent may include one or more selected from the group consisting of triethylenediamine, dimethylethanolamine, tetramethylbutanediamine, 2-methyl-triethylenediamine, dimethylcyclohexylamine, triethylamine, triisopropanolamine, 1,4-diazabicyclo(2,2,2)octane, bis(2-methylaminoethyl)ether, trimethylaminoethylethanolamine, N,N,N′,N″,N‴-pentamethyldiethylenetriamine, dimethylaminoethylamine, dimethylaminopropylamine, benzyldimethylamine, N-ethylmorpholine, N,N-dimethylaminoethylmorpholine, N,N-dimethylcyclohexylamine, 2-methyl-2-azanovonein, dibutyltin dilaurate, stannous octoate, dibutyltin diacetate, dioctyltin diacetate, dibutyltin maleate, dibutyltin di-2-ethylhexanoate, and dibutyltin dimercaptide. Specifically, the reaction rate controlling agent may include one or more selected from the group consisting of benzyldimethylamine, N,N-dimethylcyclohexylamine, and triethylamine.

The reaction rate controlling agent may be used in an amount of about 0.05 parts by weight to about 2 parts by weight, for example, about 0.05 parts by weight to about 1.8 parts by weight, for example, about 0.05 parts by weight to about 1.7 parts by weight, for example, about 0.05 parts by weight to about 1.6 parts by weight, for example, about 0.1 parts by weight to about 1.5 parts by weight, for example, about 0.1 parts by weight to about 0.3 parts by weight, for example, about 02 parts by weight to about 1.8 parts by weight, for example, about 0.2 parts by weight to about 1.7 parts by weight, for example, about 0.2 parts by weight to about 1.6 parts by weight, for example, about 0.2 parts by weight to about 1.5 parts by weight, or for example, about 0.5 parts by weight to about 1 part by weight based on 100 parts by weight of the second urethane-based prepolymer. When the reaction rate controlling agent is used in the aforementioned amount range, a polishing layer having the desired pore size and hardness may be formed by appropriately controlling the curing reaction rate of the preliminary composition.

In one embodiment, the polishing layer 10 may have a density of about 0.50 g/cm³ to about 1.20 g/cm³, for example, about 0.50 g/cm³ to about 1.10 g/cm³, for example, about 0.50 g/cm³ to about 1.00 g/cm³, for example, about 0.60 g/cm³ to about 0.90 g/cm³, or for example, about 0.70 g/cm³ to about 0.90 g/cm³. The polishing layer 10 whose density satisfies the above range can provide a polishing surface having appropriate mechanical properties to the polishing target through the polishing surface thereof, and as a result, while excellently implementing the polishing flatness of the surface to be polished, it may be advantageous in effectively preventing the occurrence of defects such as scratches, etc. In addition, the physical properties of the polishing layer 10 have excellent compatibility with mechanical and physical properties of the window 102, thereby minimizing the occurrence of leakage between the polishing layer 10 and the window 102 so that it may be more advantageous in terms of leakage prevention.

In one embodiment, the polishing layer 10 may have a tensile strength of about 15 N/mm² to about 30 N/mm², for example, about 15 N/mm² to about 28 N/mm², for example, about 15 N/mm² to about 27 N/mm², for example, about 17 N/mm² to about 27 N/mm², or for example, about 20 N/mm² to about 27 N/mm². The tensile strength was derived by processing the polishing layer to a thickness of 2 mm, cutting the width and length to a size of 4 cm × 1 cm to prepare a sample, and then measuring the highest strength value immediately before breaking at a speed of 50 mm/min using a universal testing machine (UTM) with respect to the sample. The polishing layer 10 whose tensile strength satisfies the above range may provide a polishing surface having appropriate mechanical properties to the polishing target through the polishing surface thereof, and as a result, while excellently implementing the polishing flatness of the surface to be polished, it may be advantageous in effectively preventing the occurrence of defects such as scratches, etc. In addition, the physical properties of the polishing layer 10 have excellent compatibility with mechanical and physical properties of the window 102, thereby minimizing the occurrence of leakage between the polishing layer 10 and the window 102 so that it may be more advantageous in terms of leakage prevention.

In one embodiment, the polishing layer 10 may have an elongation of about 100% or more, for example, about 100% to about 200%, or for example, about 110% to about 160%. The elongation was derived by processing the polishing layer to a thickness of 2 mm, cutting the width and length to a size of 4 cm × 1 cm to prepare a sample, measuring a maximum deformation length immediately before breaking at a speed of 50 mm/min using a universal testing machine (UTM) with respect to the sample, and then representing the ratio of the maximum deformation length to the initial length as a percentage (%). The polishing layer 10 whose elongation satisfies the above range may provide a polishing surface having appropriate mechanical properties to the polishing target through the polishing surface thereof, and as a result, while excellently implementing the polishing flatness of the surface to be polished, it may be advantageous in effectively preventing the occurrence of defects such as scratches, etc. In addition, the physical properties of the polishing layer 10 have excellent compatibility with mechanical and physical properties of the window 102, thereby minimizing the occurrence of leakage between the polishing layer 10 and the window 102 so that it may be more advantageous in terms of leakage prevention.

The support layer 20 may provide an improved leakage prevention function to the polishing pad 100 by including the compressed region CR as described above, and at the same time, may serve as a buffer that mitigates external pressure or external impact that may be transmitted to the surface to be polished during the polishing process through the non-compression region NCR.

The support layer 20 may include a nonwoven fabric or suede, but is not limited thereto. In one embodiment, the support layer 20 may include a nonwoven fabric. The ‘nonwoven fabric’ refers to a three-dimensional network structure of fibers that have not been woven. Specifically, the support layer 20 may include a nonwoven fabric and a resin impregnated into the nonwoven fabric.

The nonwoven fabric may be, for example, a nonwoven fabric of fibers including one selected from the group consisting of polyester fibers, polyamide fibers, polypropylene fibers, polyethylene fibers, and combinations thereof

The resin impregnated into the nonwoven fabric may include, for example, one selected from the group consisting of a polyurethane resin, a polybutadiene resin, a styrene-butadiene copolymer resin, a styrene-butadiene-styrene copolymer resin, an acrylonitrile-butadiene copolymer resin, a styrene-ethylene-butadiene-styrene copolymer resin, a silicone rubber resin, a polyester-based elastomer resin, a polyamide-based elastomer resin, and combinations thereof.

In one embodiment, the support layer 20 may include a nonwoven fabric of fibers including polyester fibers impregnated with a resin including a polyurethane resin. In this case, the support performance of the window 102 of the support layer 20 may be excellently implemented in the region near where the window 102 is disposed, and the uppermost end surface of the support layer 20 may be advantageous in safely loading the loaded residue without leakage in the implementation of the residue loading function by the void 15.

The support layer 20 may have a thickness of, for example, about 0.5 mm to about 2.5 mm, for example, about 0.8 mm to about 2.5 mm, for example, about 1.0 mm to about 2.5 mm, for example, about 1.0 mm to about 2.0 mm, or for example, about 1.2 mm to about 1.8 mm. Referring to FIG. 2, the thickness of the support layer 20 may be the thickness H1 of the non-compression region NCR.

The surface of the support layer 20, for example, the third surface 21 may have an Asker C hardness of about 60 to about 80, or for example, about 65 to about 80. The surface hardness on the third surface 21 satisfies the above range as the Asker C hardness so that it may be possible to sufficiently secure the supporting rigidity for supporting the polishing layer 10, and exhibit excellent interfacial adhesion with the second surface 21 using the second adhesive layer 40 as a medium.

The support layer 20 may have a density of about 0.10 g/cm³ to about 1.00 g/cm³, for example, about 0.10 g/cm³ to about 0.80 g/cm³, for example, about 0.10 g/cm³ to about 0.70 g/cm³, for example, about 0.10 g/cm³ to about 0.60 g/cm³, for example, about 0.10 g/cm³ to about 0.50 g/cm³, or for example, about 0.20 g/cm³ to about 0.40 g/cm³. The support layer 20 whose density satisfies the above range may have an excellent buffer effect based on the high elastic force of the non-compression region NCR, and since the compressed region CR is compressed at a predetermined compressibility compared to the non-compression region NCR, it may be more advantageous in forming a high-density region.

The support layer 20 may have a compressibility of about 1% to about 20%, for example, about 3% to about 15%, for example, about 5% to about 15%, or for example, about 6% to about 14%. With regard to the compressibility, the width and length of the support layer are cut to a size of 5 cm × 5 cm (thickness: 2 mm), the thickness of the cushion layer when a stress load of 85 g is maintained for 30 seconds from the no-load state is measured so that it is called T1 (mm), the thickness of the support layer is measured when a stress load of 800 g is additionally applied from the T1 state and maintained for 3 minutes so that it is called T2 (mm), and then the compressibility is calculated according to Equation of (T1-T2)/T1*100. The support layer 20 satisfies the compressibility measured under the above conditions within the above-described range so that the compressed region CR may be more advantageous in forming a high-density region effective for leakage prevention.

The support layer 20 may have a compressive modulus of elasticity of about 60% to about 95%, for example, about 70% to about 95%, or for example, about 70% to about 92%. With regard to the compressive modulus of elasticity, the width and length of the support layer are cut to a size of 5 cm × 5 cm (thickness: 2 mm), the thickness of the cushion layer when a stress load of 85 g is maintained for 30 seconds from the no-load state is measured so that it is called T1 (mm), the thickness of the support layer is measured when a stress load of 800 g is additionally applied from the T1 state and maintained for 3 minutes so that it is called T2 (mm), and then the compressive modulus of elasticity is calculated according to Equation (T3-T2)/(T1-T2)* 100 when the thickness of the support layer when the 800 g stress load is removed from the T2 state and the 85 g stress load is restored while maintaining it for 1 minute is T3. The support layer 20 satisfies the compressive modulus of elasticity measured under the above conditions within the above-described range so that the compressed region CR may be more advantageous in forming a high-density region effective for leakage prevention, and at the same time, the elastic force of the support layer 20 may be more advantageous in terms of the defect prevention effect and polishing flatness improvement with respect to the surface to be polished.

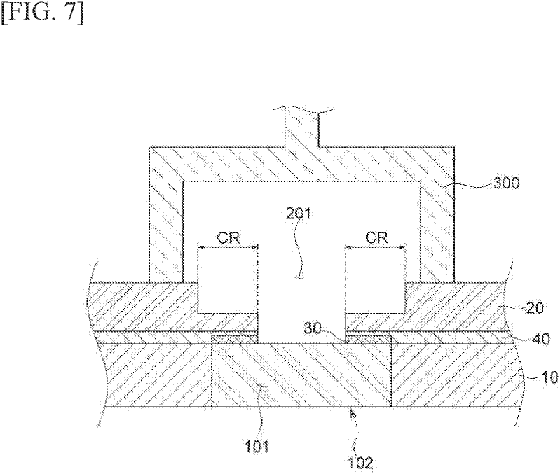

The polishing pad 100, 100′, 200 according to one embodiment may have an air leak value of about 1.0× 10⁻⁴ cc/min (0.001=1 mbar) or less, for example, about less than 1.0 × 10⁻⁴ cc/min (0.001=1 mbar), or for example, about 5.0×10⁻⁵ cc/min (0.001=1 mbar) or less. FIG. 7 schematically illustrates an air leak measurement process of the polishing pad. Referring to FIG. 7, the air leak value was derived by positioning a holder 300 in a region corresponding to the outer perimeter of the window on the lower surface of the support layer with respect to the polishing pad to seal it, performing decompression for 5 seconds under the condition of -1 bar, maintaining and stabilizing the reduced pressure state for 10 seconds, and then measuring the amount of pressure change.

In another embodiment of the present disclosure, there is provided a method for manufacturing a semiconductor device, the method comprising steps of: providing a polishing pad provided with a polishing layer which includes a first surface that is a polishing surface and a second surface that is a rear surface thereof, includes a first through-hole penetrating from the first surface to the second surface, and includes a window disposed in the first through-hole; and polishing the polishing target while rotating the polishing pad and the polishing target relative to each other under pressurized conditions after disposing the polishing target on the first surface so that a surface to be polished of the polishing target and the first surface are in contact with each other, wherein the polishing target includes a semiconductor substrate, the polishing pad further includes a support layer disposed on the second surface side of the polishing layer, the support layer includes a third surface of the polishing layer side and a fourth surface that is a rear surface thereof, and includes a second through-hole connected to the first through-hole while penetrating from the third surface to the fourth surface, the second through-hole is smaller than the first through-hole, the lowermost end surface of the window is supported by the third surface, a first adhesive layer is included between the lowermost end surface of the window and the third surface, a second adhesive layer is included between the second surface and the third surface, and between the lowermost end surface of the window and the third surface, a barrier layer is included on one surface of the second adhesive layer, and the support layer includes a compressed region in a region corresponding to the lowermost end surface of the window.

In the method for manufacturing a semiconductor device, not only when all matters related to the polishing pad are repeatedly described later, but also when they are not repeatedly described later, all matters and technical advantages thereof described for the explanation of the aforementioned embodiments may be equally integrated and applied hereinafter. The polishing pad having the aforementioned characteristics is applied to the method for manufacturing a semiconductor device so that the semiconductor device manufactured through this may secure high quality based on an excellent polishing result of the semiconductor substrate

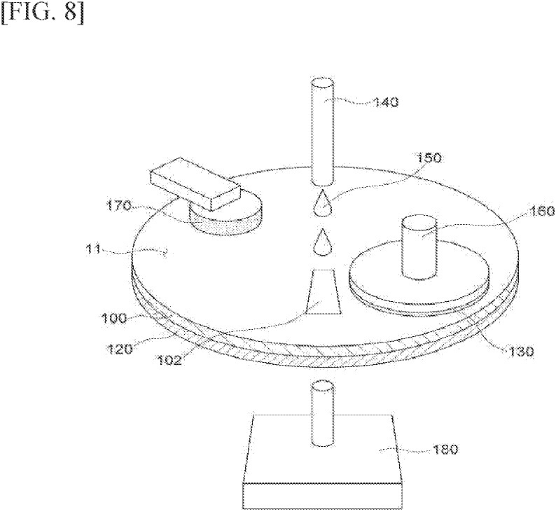

FIG. 8 is a schematic diagram schematically illustrating the method for manufacturing a semiconductor device according to one embodiment. Referring to FIG. 8, the polishing pad 100 may be provided on the surface plate 120. Referring to FIGS. 2 and 8, the polishing pad 100 may be provided on the surface plate 120 such that the second surface 12 side of the polishing layer 10 faces the surface plate 120. To describe it from other aspect, the polishing pad 100 may be disposed on the surface plate 120 such that the uppermost end surface of the window 120 and the first surface 11, which is a polishing surface, are exposed as the outermost surface.

The polishing target includes a semiconductor substrate 130. The semiconductor substrate 130 may be disposed such that a surface to be polished thereof is in contact with the first surface 11 and the uppermost end surface of the window 102. The surface to be polished of the semiconductor substrate 130 may be in direct contact with the first surface 11 and the uppermost end surfaces of the window 102, or may be in indirect contact therewith using a slurry or the like having the fluidity as a medium. In the present specification, ‘contacting’ is construed to include both cases of direct or indirect contact.

The semiconductor substrate 130 may be rotationally polished in contact with the first surface 11 and the uppermost end surface of the window 102 while it is being pressurized with a predetermined load in a state in which the semiconductor substrate 130 is mounted on the polishing head 160 such that the surface to be polished of the semiconductor substrate 130 faces the polishing pad 100. The load by which the surface to be polished of the semiconductor substrate 130 is pressurized against the first surface 11 may be selected depending on the purpose, for example, in the range of about 0.01 psi to about 20 psi, or for example, about 0.1 psi to about 15 psi, but is not limited thereto. The surface to be polished of the semiconductor substrate 130 is rotationally polished while it is being in contact with the first surface 11 and the uppermost end surfaces of the window 102 each other by the load in the aforementioned range, so that it may be more advantageous in terms of securing the effect of preventing leakage through the interface therebetween in the process of repeatedly reciprocating the first surface 11 and the uppermost end surface of the window 102.

The semiconductor substrate 130 and the polishing pad 100 may be rotated relative to each other in a state in which their respective surfaces to be polished and polishing surfaces are in contact with each other. At this time, the rotation direction of the semiconductor substrate 130 and the rotation direction of the polishing pad 100 may be the same direction or may be directions opposite to each other. In the present specification, ‘relative rotation’ is interpreted to include both of rotation in the same direction or rotation in opposite directions The polishing pad 100 is rotated by rotating the surface plate 120 in a state in which it is mounted on the surface plate 120, and the semiconductor substrate 130 is rotated by rotating the polishing head 160 in a state in which it is mounted on the polishing head 160. The rotation speed of the polishing pad 100 may be selected depending on the purpose in the range of about 10 rpm to about 500 rpm, and may be, for example, about 30 rpm to about 200 rpm, but is not limited thereto. The semiconductor substrate 130 may have a rotation speed of about 10 rpm to about 500 rpm, for example, about 30 rpm to about 200 rpm, for example, about 50 rpm to about 150 rpm, for example, about 50 rpm to about 100 rpm, or for example, about 50 rpm to about 90 rpm, but is not limited thereto. The rotation speeds of the semiconductor substrate 130 and the polishing pad 100 satisfy the above ranges so that the fluidity of the slurry due to the centrifugal force of the semiconductor substrate 130 and the polishing pad 100 may be appropriately secured in relation to the effect of preventing leakage through the interface between the uppermost end surface of the window 102 and the first surface 11. That is, the polishing slurry moves on the first surface 11 and the uppermost end surface of the window 102 at an appropriate flow rate so that the amount of the polishing slurry leaking through the interface between the uppermost end surface of the window 102 and the first surface 11 may be more advantageous in terms of maximizing the leakage prevention effect of the polishing pad 100 having the multi-stage adhesive layer structure of the first adhesive layer 30 and the second adhesive layer 40, the compressed region structure of the support layer 20, and the barrier layer at the same time.

The method for manufacturing a semiconductor device may further comprise a step of supplying a polishing slurry 150 onto the first surface 11. For example, the polishing slurry 150 may be sprayed onto the first surface 11 through a supply nozzle 140. The polishing slurry 150 sprayed through the supply nozzle 140 may have a flow rate of, for example, about 10 ml/min to about 1,000 ml/min, for example, about 10 ml/min to about 800 ml/min, or for example, about 50 ml/min to about 500 ml/min, but is not limited thereto. The spraying flow rate of the polishing slurry 150 satisfies the above range, and thus the polishing slurry moves on the first surface 11 and the uppermost end surface of the window 102 at an appropriate flow rate so that the amount of the polishing slurry leaking through the interface between the uppermost end surface of the window 102 and the first surface 11 may be more advantageous in terms of maximizing the leakage prevention effect of the polishing pad 100 having the multi-stage adhesive layer structure of the first adhesive layer 30 and the second adhesive layer 40, the compressed region structure of the support layer 20, and the barrier layer at the same time.

The polishing slurry 150 may include abrasive particles, and may include, for example, silica particles or ceria particles as the abrasive particles, but is not limited thereto.

The method for manufacturing a semiconductor device may further comprise a step of processing the first surface 11 using a conditioner 170. The step of processing of the first surface 11 through the conditioner 170 may be performed simultaneously with the step of polishing of the semiconductor substrate 130.

The conditioner 170 may process the first surface 11 while rotating. The conditioner 170 may have a rotation speed of, for example, about 50 rpm to about 150 rpm, for example, about 50 rpm to about 120 rpm, or for example, about 90 rpm to about 120 rpm.

The conditioner 170 may process the first surface 11 while being pressurized against the first surface 11. The conditioner 170 may have a pressurization load on the first surface 11 of, for example, about 1 lb to about 10 lb, or for example, about 3 lb to about 9 lb.

The conditioner 170 may process the first surface 11 while performing a vibration motion in a path reciprocating from the center of the polishing pad 100 to an end of the polishing pad 100. When the vibration motion of the conditioner 170 is calculated such that reciprocation from the center of the polishing pad 100 to the end of the polishing pad 100 is once, the conditioner 170 may have a vibration motion speed of about 10 times/min to about 30 times/min, for example, about 10 times/min to about 25 times/min, or for example, about 15 times/min to about 25 times/min.

Since the first surface 11, which is the polishing surface, is polished under the conditions that the semiconductor substrate 130 is pressurized against the polishing surface while polishing is being performed, it gradually changes to a state that is unsuitable for polishing, such as reduction of the surface roughness as the pore structure or the like exposed to the surface is pressurized. In order to prevent this, it may possible to maintain the first surface 11 in the surface state suitable for polishing while cutting the first surface 11 through the conditioner 170 having a surface capable of being subjected to roughening. At this time, when the cut portions of the first surface 11 are not quickly discharged and become debris to remain on the polishing surface, it may be a cause for the occurrence of defects such as scratches on the surface to be polished of the semiconductor substrate 130. From this point of view, the driving conditions of the conditioner 170, that is, the rotation speed and the pressurization condition, satisfy the above ranges so that the surface structure of the first surface 11 may be maintained to excellently last the leakage prevention effect of the polishing pad 100, and at the same time, may be advantageous in terms of securing the effect of preventing defects on the surface to be polished of the semiconductor substrate 130.

The method for manufacturing a semiconductor device may further comprise a step of detecting a polishing endpoint of the surface to be polished of the semiconductor substrate 130 by allowing light emitted from the light source 180 to reciprocatingly transmit the window 102. Referring to FIGS. 2 and 8, the second through-hole 201 is connected to the first through-hole 101 so that a light-path through which light emitted from the light source 180 passes through the entire thickness from the uppermost end surface of the polishing pad 100 to the lowermost end surface thereof may be secured, and the optical endpoint detection method through the window 102 may be applied.

As described above, the polishing process to which the polishing pad 100 is applied is performed while supplying a fluid such as a liquid slurry or the like onto the first surface 11. At this time, components derived from such a fluid may flow into the interface between the window 102 and the first surface 11. When the fluid components permeated like this flow into the polishing pad 100 and the lower end of the surface plate 120 after passing through the second through-hole 201, there is a concern that it may cause the light source 180 to be fixed or moisture may build up on the lowermost end surface of the window 102, which may interfere with accurate endpoint detection. From this point of view, the polishing pad 100 forms the second through-hole 201 to a size smaller than that of the first through-hole 101 to secure a support surface of the window 102 on the third surface 21. At the same time, a multi-stage adhesive layer including the first adhesive layer 30 and the second adhesive layer 40 is formed on the support surface, and a compressed region CR is provided in the region corresponding to the lowermost end surface of the window 102 of the support layer 20, and the barrier layer 50 is formed on one surface of the second adhesive layer 40 so that it may be possible to effectively prevent the fluid components derived from the polishing slurry 150 or the like from flowing into the lower end of the surface plate 120 or from causing a phenomenon that moisture builds up on the lowermost end surface of the window 102.

Hereinafter, specific Examples of the present disclosure are presented. However, Examples described below are only for specifically illustrating or explaining the present disclosure, and thus the scope of the present disclosure is not interpreted to be limited, and the scope of the present disclosure is determined by the claims.

### Preparation Example

### Preparation Example 1: Preparation of Polishing Layer Composition

72 parts by weight of 2,4-TDI, 18 parts by weight of 2,6-TDI, and 10 parts by weight of H₁₂MDI were mixed based on 100 parts by weight of the total diisocyanate component. 90 parts by weight of PTMG and 10 parts by weight of DEG were mixed based on 100 parts by weight of the total polyol component. A mixed raw material was prepared by mixing 148 parts by weight of the polyol component based on 100 parts by weight of the total diisocyanate component. The mixed raw material was inputted into a four-neck flask and then reacted at 80°C to prepare a polishing layer composition comprising a urethane-based prepolymer and having an isocyanate group content (NCO%) of 9.3% by weight.

### Preparation Example 2: Preparation of Window Composition

64 parts by weight of 2,4-TDI, 16 parts by weight of 2,6-TDI, and 20 parts by weight of H₁₂MDI were mixed based on 100 parts by weight of the total diisocyanate component. 47 parts by weight of PTMG, 47 parts by weight of PPG, and 6 parts by weight of DEG were mixed based on 100 parts by weight of the total polyol component. A mixed raw material was prepared by mixing 180 parts by weight of the polyol component based on 100 parts by weight of the total diisocyanate component. The mixed raw material was inputted into a four-neck flask and then reacted at 80°C to prepare a window composition comprising a urethane-based prepolymer and having an isocyanate group content (NCO%) of 8% by weight.

### Examples and Comparative Examples

### Example 1

1.0 part by weight of a solid-phase foaming agent (Nouryon) was mixed with respect to 100 parts by weight of the polishing layer composition of Preparation Example 1 above, and 4,4′-methylenebis(2-chloroaniline) (MOCA) was mixed as a curing agent such that the molar ratio of the amine group (-NH₂) of MOCA was 0.95 compared to that of the isocyanate group (-NCO) in the polishing layer composition of 1.0. The polishing layer composition was injected into a mold having a width of 1,000 mm, a length of 1,000 mm, and a height of 3 mm, which had been preheated to 90°C, such that it was injected at a discharge rate of 10 kg/min, and at the same time, nitrogen (N₂) gas as a gas-phase foaming agent was injected at an injection rate of 1.0 L/min. Subsequently, the preliminary composition was subjected to a post-curing reaction under a temperature condition of 110°C to prepare a polishing layer. The polishing layer was subjected to turning to a thickness of 2.03 mm, and grooves with a concentric circular structure having a depth of 460 µm, a width of 0.85 mm, and a pitch of 3.0 mm were processed on the polishing surface.

4,4′-methylenebis(2-chloroaniline) (MOCA) was mixed as a curing agent with respect to 100 parts by weight of the window composition of Preparation Example 2 such that the molar ratio of the amine group (-NH₂) of MOCA was 0.95 compared to that of the isocyanate group (-NCO) in the polishing layer composition of 1.0. The window composition was injected into a mold having a width of 1,000 mm, a length of 1,000 mm, and a height of 3 mm, which had been preheated to 90°C, such that it was injected at a discharge rate of 10 kg/min, and the post curing reaction was performed under a temperature condition of 110°C to manufacture a window. The window was manufactured such that the respective thickness values satisfy Table 1 below, and it was manufactured such that the width and length were 60 mm and 20 mm, respectively.

A support layer having a structure in which a urethane-based resin is impregnated in a nonwoven fabric including polyester resin fibers and having a thickness of 1.4 mm was prepared.

After disposing an adhesive film including a thermoplastic urethane-based adhesive on the rear surface (second surface) of the polishing surface of the polishing layer, a first through-hole was formed to penetrate from the first surface, which is the polishing surface of the polishing layer, to the second surface. However, the first through-hole was formed in a rectangular parallelepiped shape such that the width and length of the first through-hole were 20 mm and 60 mm, respectively.

Subsequently, a barrier layer having a polyvinylidene chloride (PVDC) hydrophobic barrier coating with a thickness of 1 µm formed therein was prepared on a polyethylene terephthalate (PET) film with a thickness of 11.5 µm, an adhesive film containing a thermoplastic urethane-based adhesive was disposed on one surface (third surface) of the support layer, the barrier layer was disposed on the adhesive film, the barrier layer and the polishing layer were laminated to each other such that the barrier layer was in contact with the second surface of the polishing layer, and then heat fusion was performed at 140° C. using a pressurization roller to form a second adhesive layer.

Subsequently, cutting processing was performed from the lowermost end surface of the support layer to form a second through-hole penetrating the support layer in the thickness direction, the second through-hole was manufactured to be connected to the first through-hole each other by forming the second through-hole in a region corresponding to the first through-hole, and the second through-hole was formed in a rectangular parallelepiped shape such that the width and length of the second through-hole were 52 mm and 14 mm, respectively.

Referring to FIG. 2, since the second through-hole 201 was formed to a size smaller than that of the first through-hole 101, a moisture-curable adhesive composition comprising about 97.75 (±1.25)% by weight of a urethane-based prepolymer polymerized from a monomer component including the aromatic diisocyanate of Chemical Formula 1 above and a polyol, and about 2.25 (±1.25)% by weight of the unreacted aromatic diisocyanate of Chemical Formula 1 above was applied to the upper portion of the second adhesive layer 40 exposed to the outside, and then aged for 2 hours. At this time, the moisture-curable adhesive composition was applied using a dispenser provided with a supply nozzle having a diameter of 100 µm Subsequently, the window 102 was disposed in the first through-hole 101 so as to be supported by the surface to which the moisture-curable adhesive composition was applied, pressurized with a load of 100N for 1 second, and then further pressurized with a load of 900 N for 10 seconds.

Subsequently, a compressed region CR was formed in a predetermined region in a direction from the side surface of the second through-hole 201 toward the inside of the support layer 20 by pressurizing the lowermost end surface (fourth surface) of the support layer 20.

As a result, a polishing pad having a total thickness of 3.4 mm which includes a multi-stage adhesive layer of the first adhesive layer 30 and the second adhesive layer at the lowermost end surface side of the window, includes a barrier layer, and includes a compressed region (CR) in the support layer was manufactured.

The respective dimensions related to the first adhesive layer, the second adhesive layer, the compressed region and non-compression region of the support layer, and the grooves are as shown in Table 1 below.

### Example 2

A polishing pad was manufactured in the same manner as in the Example 1 except that, instead of the barrier layer, a barrier layer having an aluminum (Al) deposition layer with a thickness of 0.1 µm formed thereon was applied onto a polyethylene terephthalate (PET) film with a thickness of 18.9 µm.

### Comparative Example 1

A polishing pad was manufactured in the same manner as in the Example 1 except that the first adhesive layer was not disposed between the side surface of the first through-hole and the side surface of the window, the barrier layer was not present, and a compressed region was present in the support layer.

### Comparative Example 2

A polishing pad was manufactured in the same manner as in the Example 1 except that a compressed region was not present in the support layer, the barrier layer was not present, and the first adhesive layer was present.

### Comparative Example 3

A polishing pad was manufactured in the same manner as in the Example 1 except that the barrier layer was not present.

### Evaluation and Measurement

### Measurement Example 1: Evaluation of Surface Hardness of Polishing Layer and Window

A sample was prepared by cutting the polishing layer of each of the Examples and Comparative Examples to a size of 3 cm × 3 cm in width and length respectively. A window sample was prepared by cutting the window of each of the Examples and Comparative Examples to a size of 3 cm × 3 cm in width and length respectively. After the sample was stored at a temperature of 25° C. for 12 hours, Shore D hardness values were measured using a hardness meter to determine surface hardness values (S1, S2) in a room temperature dry state. In addition, the window sample was immersed in water at a temperature of 30° C., water at a temperature of 50° C., and water at a temperature of 70° C. for 30 minutes, and then Shore D hardness values were measured using a hardness meter to determine 30° C. wet hardness values (S3), 50° C. wet hardness values (S4), and 70° C. wet hardness values (S5) respectively The results are as shown in Table 1 respectively.

### Measurement Example 2: Leak Test

The polishing pad of each of the Examples and Comparative Examples was mounted on a surface plate of polishing equipment (CTS AP300), a silicon wafer (TEOS wafer) was mounted on a polishing head, polishing was carried out for 50 hours or more until all the grooves of the polishing pad were worn out under a rotation speed of the polishing head of 87 rpm, a pressure load of the polishing head of 3.5 psi on the polishing pad, a rotation speed of the surface plate of 93 rpm, an injection flow rate of distilled water (DI water) of 200 mL/min, a rotation speed of the conditioner (CI 45) of 101 rpm, and a conditioner vibration motion speed of 19 times/min, and leakage was checked once every hour. Subsequently, after performing visual check over the entire evaluation time, ‘none’ was indicated if condensation occurred on the lowermost end surface of the window or a phenomenon in which moisture builds up on the surface plate did not occur, and the polishing time up to the time of occurrence was indicated if condensation occurred on the lowermost end surface of the window or the phenomenon in which moisture builds up on the surface plate occurred. The leak test results are as shown in Table 1 below.

### Measurement Example 3: Air Leak Test

FIG. 7 schematically illustrates an air leak measurement process of the polishing pad. Referring to FIG. 7, the air leak values were derived by positioning a holder in a region corresponding to the outer perimeter of the window on the lower surface of the support layer with respect to the polishing pad of each of the Examples and Comparative Examples to seal it, performing decompression for 5 seconds under the condition of -1 bar, maintaining and stabilizing the reduced pressure condition for 10 seconds, and then measuring the amount of pressure change. The results are as shown in Table 1 below.

TABLE 1

| Item | | | Unit | Example 1 | Example 2 | Comparative Example 1 | Comparative Example 2 | Comparative Example 3 |
|---|---|---|---|---|---|---|---|---|
| Total thickness of polishing pad | | | mm | 3.4 | 3.4 | 3.4 | 3.4 | 3.4 |
| Thickness of polishing layer (D1) | | | mm | 2.03 | 2.03 | 2.03 | 2.03 | 2.03 |
| Thickness of window (D2) | | | mm | 2.04 | 2.04 | 2.04 | 2.04 | 2.04 |
| Step difference between polishing surface and uppermost end surface of window (d3) | | | µm | 100 | 100 | 100 | 100 | 100 |
| Depth of recess portion (d2) | | | mm | 0 | 0 | 0 | 0 | 0 |
| Thickness of second adhesive layer | | | µm | 27 | 27 | 27 | 27 | 27 |
| First adhesive layer | Length of side surface (L1) | | µm | 4 | 4 | - | 4 | 4 |
| | Width (W3) | Width of window | mm | 3 | 3 | - | 3 | 3 |
| | | Length of window | mm | 4 | 4 | - | 4 | 4 |
| Barrier layer | Material | | - | PVDC-coated PET film | A1-deposited PET film | - | - | - |
| | Thickness | | µm | 12.5 | 19 | - | - | - |
| | Density | | g/cm³ | 1.4 | 1.4 | - | - | - |
| | Wet permeability | | g/m²/day | 8 | 2 | - | - | - |
| | Tensile strength | | Kgf/mm² | 30 | 27 | - | - | - |
| | Elongation | | % | 140 | 130 | - | - | - |

| | | | | | | | | |
|---|---|---|---|---|---|---|---|---|
| Support layer | NCR | Thickness (H1) | mm | 1.4 | 1.4 | 1.4 | 1.4 | 1.4 |
| | CR | Width (CR) | mm | 7.5 | 7.5 | 7.5 | - | 7.5 |
| | | Thickness (H2) | mm | 0.48 | 0.48 | 0.48 | - | 0.48 |
| Groove | Depth (d1) | | µm | 460 | 460 | 460 | 460 | 460 |
| | Width (w1) | | mm | 0.85 | 0.85 | 0.85 | 0.85 | 0.85 |
| | Pitch (p1) | | mm | 3.0 | 3.0 | 3.0 | 3.0 | 3.0 |
| Shore D hardness | Polishing surface | Room temperature dry (S1) | - | 60 | 60 | 58 | 59 | 59 |
| | Uppermost end surface of window | 30°C wet (s3) | - | 62.2 | 61.9 | 58.9 | 60.1 | 60.5 |
| | | 50°C wet (S4) | - | 58.9 | 59.4 | 57.5 | 57.7 | 57.6 |
| | | 70°C wet (S5) | - | 55.2 | 55.7 | 53.5 | 53.6 | 53.4 |
| | | Room temperature dry (S2) | - | 63.2 | 63.5 | 59.3 | 60.8 | 61.1 |
| | \| S1-S2 \| | | - | 3.2 | 3.5 | 1.3 | 1.8 | 2.1 |
| | \| S2-S3 \| | | - | 1 | 1.6 | 0.4 | 0.7 | 0.6 |
| | \| S2-S4 \| | | - | 4.3 | 4.1 | 1.8 | 3.1 | 3.5 |
| | \| S2-S5 \| | | - | 8 | 7.8 | 5.8 | 7.2 | 7.7 |

| | | | | | | |
|---|---|---|---|---|---|---|
| Leak test | Hour | None | None | 8 | 11 | 28 |
| Air leak | cc/min | 2.6×10⁻⁵ | 3.5×10⁻⁵ | 9.2×10⁻¹ | 4.3× 10⁻³ | 2.1 × 10⁻⁴ |

Referring to the results of Table 1, it could be confirmed that the polishing pads of the Examples 1 and 2 exhibited air leak values of 1.0× 10⁻⁴ cc/min (0.001 = 1 mbar) or less, more specifically, less than 5.0× 10⁻⁵ cc/min (0.001 = 1 mbar), and exhibited excellent leak test results by, while the lowermost end surface of the window is being supported by the third surface of the support layer, having a multi-stage adhesive layer of a first adhesive layer and a second adhesive layer between the lowermost end surface of the window and the third surface of the support layer and allowing the support layer to have a compressed region in the region corresponding to the lowermost end surface of the window at the same time, and including the barrier layer along with this. On the contrary, the polishing pads of the Comparative Examples 1 to 3 are polishing pads that lack at least one of the multi-stage adhesive layer, the compressed region, and the barrier layer, and it could be confirmed that the polishing pads of the Comparative Examples 1 to 3 exhibited inferior leakage prevention effects compared to the polishing pads of the Examples 1 and 2.

As described above, the polishing pad according to one embodiment is a polishing pad capable of detecting an endpoint by applying a window, and may function as a process component capable of manufacturing an excellent semiconductor device by applying the multi-stage adhesive layer structure to the lowermost end surface of the window and having the compressed region in a specific region of the support layer at the same time, and applying the barrier layer, so that the negative factor due to the local heterogeneity of the portion where the window is introduced, that is, the possibility of leakage occurrence is substantially eliminated, thereby maximally extending the life of the polishing pad requiring the replacement after use for a predetermined period of time and maximizing the effect of preventing leakage during use of the polishing pad.

Explanation of reference numerals
100, 100′, 200: Polishing pad
10: Polishing layer
11: First surface, Polishing surface
12: Second surface
101: First through-hole
102: Window
20: Support layer
21: Third surface
22: Fourth surface
201: Second through-hole
30: First adhesive layer
40: Second adhesive layer
50: Barrier layer
111: Groove
112: Pore
113: Fine concave portion
103: Recess portion
300: Holder
120: Surface plate
130: Semiconductor substrate
140: Supply nozzle
150: Polishing slurry
160: Polishing head
170: Conditioner
180: Light source
CR: Compressed region (width of)
NCR: Non-compression region
D1: Thickness of polishing layer
D2: Thickness of window
d1: Depth of groove
d2: Depth of recess portion
d3: Step difference between first surface and uppermost end surface of window
L1: Length of first adhesive layer
W2: Width of window support surface of third surface
W3: Width of first adhesive layer
H1: Thickness of non-compression region
H2: Thickness of compressed region
w1: Width of groove
p1: Pitch of groove

What is claimed is:

1. A polishing pad comprising:
a polishing layer including a first surface that is a polishing surface and a second surface that is a rear surface thereof, and including a first through-hole penetrating from the first surface to the second surface;
a window disposed in the first through-hole; and
a support layer which is disposed on the second surface side of the polishing layer, includes a third surface of the polishing layer side and a fourth surface that is a rear surface thereof, and includes a second through-hole connected to the first through-hole while penetrating from the third surface to the fourth surface,
wherein the second through-hole is smaller than the first through-hole,
the lowermost end surface of the window is supported by the third surface,
a first adhesive layer is included between the lowermost end surface of the window and the third surface,
a second adhesive layer is included between the second surface and the third surface, and between the lowermost end surface of the window and the third surface,
a barrier layer is included on one surface of the second adhesive layer, and
the support layer includes a compressed region in a region corresponding to the lowermost end surface of the window.

2. The polishing pad of claim 1, wherein the first adhesive layer includes a moisture-curable resin, and the second adhesive layer includes a thermoplastic resin.

3. The polishing pad of claim 1, wherein the first adhesive layer is not disposed between the side surface of the first through-hole and the side surface of the window.

4. The polishing pad of claim 1, wherein the first adhesive layer is disposed also between the side surface of the first through-hole and the side surface of the window.

5. The polishing pad of claim 1, wherein the barrier layer includes one selected from the group consisting of a resin film, a metal-deposited resin film, an inorganic film-deposited resin film, a hydrophobic barrier coating resin film, a particledispersed resin film, an inorganic film, a metal film, and combinations thereof.

6. The polishing pad of claim 1, wherein the barrier layer has a wet permeability of less than 45 g/m²/day.

7. The polishing pad of claim 1, wherein the barrier layer has a thickness of 5 µm to 50 µm.

8. The polishing pad of claim 1, wherein the barrier layer has a density of 0.8 g/cm³ to 2.0 g/cm³.

9. The polishing pad of claim 1, wherein the barrier layer has a tensile strength of 10 kgf/mm² to 50 kgf/mm².

10. The polishing pad of claim 1, wherein the barrier layer has an elongation of 100% to 160%.

11. The polishing pad of claim 1, wherein the support layer includes a non-compression region in a region except for the compressed region, and a percentage of the thickness of the compressed region to the thickness of the non-compression region is 0.01% to 80%.

12. The polishing pad of claim 1, wherein the first surface includes at least one groove, and the groove has a depth of 100 µm to 1,500 µm and a width of 0. 1 mm to 20 mm.

13. The polishing pad of claim 12, wherein the first surface includes a plurality of grooves, the plurality of grooves include concentric circular grooves, and the concentric circular grooves have a distance between two adjacent grooves of 2 mm to 70 mm.

14. The polishing pad of claim 1, wherein the lowermost end surface of the window includes a recess portion.

15. The polishing pad of claim 14, wherein the recess portion has a depth of 0.1 mm to 2.5 mm.

16. The polishing pad of claim 1, wherein the window includes a non-foamed cured product of a window composition comprising a first urethane-based prepolymer, and the polishing layer includes a foamed cured product of a polishing layer composition comprising a second urethane-based prepolymer.

17. The polishing pad of claim 1, wherein the Shore D hardness measured in a room temperature dry state with respect to the first surface is smaller than the Shore D hardness measured in the room temperature dry state with respect to the uppermost end surface of the window.

18. A method for manufacturing a semiconductor device, the method comprising steps of
providing a polishing pad provided with a polishing layer which includes a first surface that is a polishing surface and a second surface that is a rear surface thereof, includes a first through-hole penetrating from the first surface to the second surface, and includes a window disposed in the first through-hole; and
polishing the polishing target while rotating the polishing pad and the polishing target relative to each other under pressurized conditions after disposing the polishing target on the first surface so that a surface to be polished of the polishing target and the first surface are in contact with each other,
wherein the polishing target includes a semiconductor substrate,
the polishing pad further includes a support layer disposed on the second surface side of the polishing layer,
the support layer includes a third surface of the polishing layer side and a fourth surface that is a rear surface thereof, and includes a second through-hole connected to the first through-hole while penetrating from the third surface to the fourth surface,
the second through-hole is smaller than the first through-hole,
the lowermost end surface of the window is supported by the third surface,
a first adhesive layer is included between the lowermost end surface of the window and the third surface,
a second adhesive layer is included between the second surface and the third surface, and between the lowermost end surface of the window and the third surface,
a barrier layer is included on one surface of the second adhesive layer, and
the support layer includes a compressed region in a region corresponding to the lowermost end surface of the window.

19. The method of claim 18, further comprising a step of supplying a polishing slurry onto the first surface,
wherein the polishing slurry is sprayed onto the first surface through a supply nozzle, and
the polishing slurry sprayed through the supply nozzle has a flow rate of 10 ml/min to 1,000 ml/min.

20. The method of claim 18, wherein the polishing target and the polishing pad each have a rotation speed of 10 rpm to 500 rpm.
